(19) United States
(12) Patent Application Publication
(10) Pub. No.: US 2026/0231055 A1
(43) Pub. Date: Aug. 6, 2026

(54) METHODS FOR AUTOMATIC GAIN CONTROL

(71) Applicant: QUALCOMM Incorporated, San Diego, CA (US)

(72) Inventors: Chih-Hao LIU, San Diego, CA (US); Giovanni CHISCI, San Diego, CA (US); Stelios STEFANATOS, San Diego, CA (US); Jing SUN, San Diego, CA (US)

(21) Appl. No.: 19/130,812

(22) PCT Filed: Sep. 1, 2023
(86) PCT No.: PCT/US2023/073323

§ 371 Date: May 16, 2025

(30) Foreign Application Priority Data
Jan. 26, 2023 (GR) 20230100059

(51) Int. Cl. H04W 52/52; H04L 5/00; H04L 25/02; H04W 72/0446; H04W 72/25

(52) U.S. Cl. CPC H04W 52/52; H04L 5/0051; H04L 25/0204; H04W 72/0446; H04W 72/25

(57) ABSTRACT

Methods, systems, and devices for wireless communications are described. A user equipment (UE) may perform automatic gain control (AGC) operations multiple times within a slot. A UE may receive control signaling indicating a parameter that specifies that AGC should be performed at a first symbol period of a mini-slot. A UE may not receive the control signaling and may instead perform an energy detection operation to determine whether it should perform a second instance of AGC during a slot. The energy detection operation may be for detecting whether subslot-based communications are being transmitted by other UEs. A UE that transmits subslot-based communications may determine to reduce gain for or otherwise refrain from transmitting the subslot-based communications if the UE detects slot-based communications within a specific frequency range.

### CROSS REFERENCES

The present Application is a 371 national stage filing of International PCT Application No. PCT/US2023/073323 by LIU et al. entitled “METHODS FOR AUTOMATIC GAIN CONTROL,” filed Sep. 1, 2023; and claims priority to Greek Patent Application No. 20230100059 by LIU et al., entitled “METHODS FOR AUTOMATIC GAIN CONTROL,” filed Jan. 26, 2023, each of which is assigned to the assignee hereof, and each of which is expressly incorporated by reference in its entirety herein.

### FIELD OF TECHNOLOGY

The following relates to wireless communications, including methods for automatic gain control.

### BACKGROUND

Wireless communications systems are widely deployed to provide various types of communication content such as voice, video, packet data, messaging, broadcast, and so on. These systems may be capable of supporting communication with multiple users by sharing the available system resources (e.g., time, frequency, and power). Examples of such multiple-access systems include fourth generation (4G) systems such as Long Term Evolution (LTE) systems, LTE-Advanced (LTE-A) systems, or LTE-A Pro systems, and fifth generation (5G) systems which may be referred to as New Radio (NR) systems. These systems may employ technologies such as code division multiple access (CDMA), time division multiple access (TDMA), frequency division multiple access (FDMA), orthogonal FDMA (OFDMA), or discrete Fourier transform spread orthogonal frequency division multiplexing (DFT-S-OFDM). A wireless multiple-access communications system may include one or more base stations, each supporting wireless communication for communication devices, which may be known as user equipment (UE).

Wireless communication systems, in some cases, may support communications using different transmission time intervals (TTIs) (e.g., different resource configurations, different resources pools). For example, some network devices may communicate using slot-based resources (e.g., slots) and some other network devices may communicate using subslot-based resources (e.g., mini-slots). Additionally, or alternatively, some devices may be capable of communicating using multiple TTIs (e.g., slot-based resources and subslot-based resources). In such cases, a network device such as a UE or network entity may receive both slot-based communications and subslot-based communications. Additionally, or alternatively, some subslot-based communications may be received within a slot or may otherwise overlap in time with slot-based communications. However, the co-occurrence of slot-based and subslot-based communications may present communication challenges.

### SUMMARY

The described techniques relate to improved methods, systems, devices, and apparatuses that support methods for automatic gain control. For example, the described techniques provide for a user equipment (UE) to perform automatic gain control (AGC) operations multiple times within a slot, which may make gain settings more appropriate (e.g., effective) if subslot-based communications are received during the slot. For example, a UE may receive control signaling (e.g., from a network entity, from a different UE) indicating that AGC (e.g., a second instance of AGC) should be performed at a first symbol period of a mini-slot. In some other cases, a UE may not receive the control signaling and may instead perform an energy detection operation to determine whether it should perform a second instance of AGC during a slot. Additionally, or alternatively, a UE that transmits subslot-based communications may determine to reduce gain for or otherwise refrain from transmitting the subslot-based communications if the UE detects slot-based communications within a specific frequency range.

A method for wireless communications at a first UE is described. The method may include identifying an automatic gain control parameter that indicates to perform multiple automatic gain control procedures during a slot of a sidelink channel, or the automatic gain control parameter indicates to perform the multiple automatic gain control procedures during the slot based on an energy detection result for a defined symbol period of the slot, the defined symbol period occurring after a beginning symbol period of the slot, performing, based on the identifying, a first automatic gain control procedure of the multiple automatic gain control procedures on the beginning symbol period of the slot of to determine a first gain state for receiving a sidelink grant via a sidelink control channel of the slot, receiving, via the sidelink control channel in accordance with the first gain state, the sidelink grant indicating that a sidelink transmission is scheduled for the first UE in a sidelink shared data channel of the slot, and receiving, using the first gain state and a second gain state determined in accordance with the automatic gain control parameter, the sidelink transmission via the sidelink shared data channel of the slot.

An apparatus for wireless communications at a first UE is described. The apparatus may include one or more processors, one or more memories coupled with the one or more processors, and instructions stored in the one or more memories. The instructions may be executable by the one or more processors to cause the apparatus to identify an automatic gain control parameter that indicates to perform multiple automatic gain control procedures during a slot of a sidelink channel, or the automatic gain control parameter indicates to perform the multiple automatic gain control procedures during the slot based on an energy detection result for a defined symbol period of the slot, the defined symbol period occurring after a beginning symbol period of the slot, perform, based on the identifying, a first automatic gain control procedure of the multiple automatic gain control procedures on the beginning symbol period of the slot of to determine a first gain state for receiving a sidelink grant via a sidelink control channel of the slot, receive, via the sidelink control channel in accordance with the first gain state, the sidelink grant indicating that a sidelink transmission is scheduled for the first UE in a sidelink shared data channel of the slot, and receive, using the first gain state and a second gain state determined in accordance with the automatic gain control parameter, the sidelink transmission via the sidelink shared data channel of the slot.

Another apparatus for wireless communications at a first UE is described. The apparatus may include means for identifying an automatic gain control parameter that indicates to perform multiple automatic gain control procedures during a slot of a sidelink channel, or the automatic gain control parameter indicates to perform the multiple automatic gain control procedures during the slot based on an energy detection result for a defined symbol period of the slot, the defined symbol period occurring after a beginning symbol period of the slot, means for performing, based on the identifying, a first automatic gain control procedure of the multiple automatic gain control procedures on the beginning symbol period of the slot of to determine a first gain state for receiving a sidelink grant via a sidelink control channel of the slot, means for receiving, via the sidelink control channel in accordance with the first gain state, the sidelink grant indicating that a sidelink transmission is scheduled for the first UE in a sidelink shared data channel of the slot, and means for receiving, using the first gain state and a second gain state determined in accordance with the automatic gain control parameter, the sidelink transmission via the sidelink shared data channel of the slot.

A non-transitory computer-readable medium storing code for wireless communications at a first UE is described. The code may include instructions executable by one or more processors to identify an automatic gain control parameter that indicates to perform multiple automatic gain control procedures during a slot of a sidelink channel, or the automatic gain control parameter indicates to perform the multiple automatic gain control procedures during the slot based on an energy detection result for a defined symbol period of the slot, the defined symbol period occurring after a beginning symbol period of the slot, perform, based on the identifying, a first automatic gain control procedure of the multiple automatic gain control procedures on the beginning symbol period of the slot of to determine a first gain state for receiving a sidelink grant via a sidelink control channel of the slot, receive, via the sidelink control channel in accordance with the first gain state, the sidelink grant indicating that a sidelink transmission is scheduled for the first UE in a sidelink shared data channel of the slot, and receive, using the first gain state and a second gain state determined in accordance with the automatic gain control parameter, the sidelink transmission via the sidelink shared data channel of the slot.

Some examples of the method, apparatuses, and non-transitory computer-readable medium described herein may further include operations, features, means, or instructions for performing a first channel estimation procedure for the sidelink shared data channel during a second symbol period of the slot, the first channel estimation procedure using the first gain state and performing a second channel estimation procedure for the sidelink shared data channel during a third symbol period of the slot, the second channel estimation procedure using the second gain state.

Some examples of the method, apparatuses, and non-transitory computer-readable medium described herein may further include operations, features, means, or instructions for receiving a first demodulation reference signal during a second symbol period of the slot, the second symbol period subsequent to the beginning symbol period of the slot and receiving a second demodulation reference signal during a third symbol period of the slot, the third symbol period of the slot subsequent to the defined symbol period of the slot.

In some examples of the method, apparatuses, and non-transitory computer-readable medium described herein, the slot includes a set of multiple demodulation reference signal symbol periods and a set of multiple automatic gain control symbol periods, each automatic gain control symbol period of the set of multiple automatic gain control symbol periods configured based on a pattern for the set of multiple demodulation reference signal symbol periods.

In some examples of the method, apparatuses, and non-transitory computer-readable medium described herein, the slot includes a first demodulation reference signal symbol period subsequent to a first automatic gain control symbol period and a second demodulation reference signal symbol period subsequent to a second automatic gain control symbol period.

In some examples of the method, apparatuses, and non-transitory computer-readable medium described herein, the slot includes a same quantity of demodulation reference signal symbol periods and automatic gain control symbol periods.

Some examples of the method, apparatuses, and non-transitory computer-readable medium described herein may further include operations, features, means, or instructions for receiving, from a network entity, control signaling indicating the automatic gain control parameter that indicates to perform a second automatic gain control procedure, where the control signaling may be based on whether a quantity of communication links established with the network entity may be configured for communications using subslots.

In some examples of the method, apparatuses, and non-transitory computer-readable medium described herein, the control signaling includes a medium access control control element, radio resource control signaling, or a downlink control information grant, the control signaling received semi-statically.

Some examples of the method, apparatuses, and non-transitory computer-readable medium described herein may further include operations, features, means, or instructions for receiving, from a second UE, control signaling indicating the automatic gain control parameter that indicates to perform a second automatic gain control procedure, where the control signaling may be based on the second UE transmitting an automatic gain control signal on the defined symbol period of the slot.

Some examples of the method, apparatuses, and non-transitory computer-readable medium described herein may further include operations, features, means, or instructions for receiving, from a second UE, control signaling indicating the automatic gain control parameter that indicates to perform a second automatic gain control procedure based on an indication from a network entity to perform the second automatic gain control procedure.

Some examples of the method, apparatuses, and non-transitory computer-readable medium described herein may further include operations, features, means, or instructions for measuring an energy detection result for a third symbol period of the slot, the defined symbol period of the slot subsequent to the third symbol period of the slot, measuring the energy detection result for the defined symbol period of the slot, and comparing the energy detection result for the third symbol period to the energy detection result for the defined symbol period, where a second automatic gain control procedure may be performed on the defined symbol period of the slot based on the comparing.

Some examples of the method, apparatuses, and non-transitory computer-readable medium described herein may further include operations, features, means, or instructions for puncturing the defined symbol period based on a difference between an energy detection result for a third symbol period and the energy detection result for the defined symbol period exceeding a threshold difference.

In some examples of the method, apparatuses, and non-transitory computer-readable medium described herein, the defined symbol period of the slot overlaps with a second beginning symbol period of a subslot of the slot.

A method for wireless communications is described. The method may include performing a channel access procedure within frequency resources positioned relative to a first sidelink frequency band to monitor for sidelink control information, a sidelink reference signal, or both, to determine whether full slot transmission by a second UE is scheduled to occur within a first slot, the frequency resources occurring within a threshold frequency offset of the first sidelink frequency band, transmitting a sidelink grant indicating that one or more messages are scheduled for transmission via the first sidelink frequency band in a subslot of the first slot, and transmitting, in the subslot, the one or more messages via the first sidelink frequency band based on the channel access procedure indicating that the frequency resources are available during the first slot.

An apparatus for wireless communications is described. The apparatus may include one or more processors, one or more memories coupled with the one or more processors, and instructions stored in the one or more memories. The instructions may be executable by the one or more processors to cause the apparatus to perform a channel access procedure within frequency resources positioned relative to a first sidelink frequency band to monitor for sidelink control information, a sidelink reference signal, or both, to determine whether full slot transmission by a second UE is scheduled to occur within a first slot, the frequency resources occurring within a threshold frequency offset of the first sidelink frequency band, transmit a sidelink grant indicating that one or more messages are scheduled for transmission via the first sidelink frequency band in a subslot of the first slot, and transmit, in the subslot, the one or more messages via the first sidelink frequency band based on the channel access procedure indicating that the frequency resources are available during the first slot.

Another apparatus for wireless communications is described. The apparatus may include means for performing a channel access procedure within frequency resources positioned relative to a first sidelink frequency band to monitor for sidelink control information, a sidelink reference signal, or both, to determine whether full slot transmission by a second UE is scheduled to occur within a first slot, the frequency resources occurring within a threshold frequency offset of the first sidelink frequency band, means for transmitting a sidelink grant indicating that one or more messages are scheduled for transmission via the first sidelink frequency band in a subslot of the first slot, and means for transmitting, in the subslot, the one or more messages via the first sidelink frequency band based on the channel access procedure indicating that the frequency resources are available during the first slot.

A non-transitory computer-readable medium storing code for wireless communications is described. The code may include instructions executable by a processor to perform a channel access procedure within frequency resources positioned relative to a first sidelink frequency band to monitor for sidelink control information, a sidelink reference signal, or both, to determine whether full slot transmission by a second UE is scheduled to occur within a first slot, the frequency resources occurring within a threshold frequency offset of the first sidelink frequency band, transmit a sidelink grant indicating that one or more messages are scheduled for transmission via the first sidelink frequency band in a subslot of the first slot, and transmit, in the subslot, the one or more messages via the first sidelink frequency band based on the channel access procedure indicating that the frequency resources are available during the first slot.

Some examples of the method, apparatuses, and non-transitory computer-readable medium described herein may further include operations, features, means, or instructions for receiving control signaling indicating the threshold frequency offset for monitoring for the sidelink control information, the sidelink reference signal, or both, relative to a target sidelink frequency band.

In some examples of the method, apparatuses, and non-transitory computer-readable medium described herein, receiving the control signaling may include operations, features, means, or instructions for receiving the control signaling from the second UE.

Some examples of the method, apparatuses, and non-transitory computer-readable medium described herein may further include operations, features, means, or instructions for performing a second channel access procedure within frequency resources positioned relative to the first sidelink frequency band to monitor for the sidelink control information, the sidelink reference signal, or both and refraining from transmitting one or more second messages via the first sidelink frequency band based on the second channel access procedure indicating that the frequency resources may be unavailable.

Some examples of the method, apparatuses, and non-transitory computer-readable medium described herein may further include operations, features, means, or instructions for reducing a gain for one or more transmitting components of the first UE based on a reference signal receive power and a priority for the sidelink control information, the sidelink reference signal, or both.

In some examples of the method, apparatuses, and non-transitory computer-readable medium described herein, the frequency resources may be adjacent to the first sidelink frequency band.

The foregoing has outlined rather broadly the features and technical advantages of examples according to the disclosure in order that the detailed description that follows may be better understood. Additional features and advantages will be described hereinafter. The conception and specific examples disclosed may be readily utilized as a basis for modifying or designing other structures for carrying out the same purposes of the present disclosure. Such equivalent constructions do not depart from the scope of the appended claims. Characteristics of the concepts disclosed herein, both their organization and method of operation, together with associated advantages will be better understood from the following description when considered in connection with the accompanying figures. Each of the figures is provided for the purposes of illustration and description, and not as a definition of the limits of the claims.

While aspects and embodiments are described in this application by illustration to some examples, those skilled in the art will understand that additional implementations and use cases may come about in many different arrangements and scenarios. Innovations described herein may be implemented across many differing platform types, devices, systems, shapes, sizes, packaging arrangements. For example, embodiments and/or uses may come about via integrated chip embodiments and other non-module-component based devices (e.g., end-user devices, vehicles, communication devices, computing devices, industrial equipment, retail/purchasing devices, medical devices, artificial intelligence (AI)-enabled devices, etc.). While some examples may or may not be specifically directed to use cases or applications, a wide assortment of applicability of described innovations may occur. Implementations may range in spectrum from chip-level or modular components to non-modular, non-chip-level implementations and further to aggregate, distributed, or original equipment manufacturer (OEM) devices or systems incorporating one or more aspects of the described innovations. In some practical settings, devices incorporating described aspects and features may also necessarily include additional components and features for implementation and practice of claimed and described embodiments. For example, transmission and reception of wireless signals necessarily includes a number of components for analog and digital purposes (e.g., hardware components including antenna, radio frequency (RF)-chains, power amplifiers, modulators, buffer, processor(s), interleaver, adders/summers, etc.). It is intended that innovations described herein may be practiced in a wide variety of devices, chip-level components, systems, distributed arrangements, end-user devices, etc. of varying sizes, shapes, and constitution.

### BRIEF DESCRIPTION OF THE DRAWINGS

FIG. 1 illustrates an example of a wireless communications system that supports methods for automatic gain control in accordance with one or more aspects of the present disclosure.

FIG. 2 illustrates an example of a network architecture that supports methods for automatic gain control in accordance with one or more aspects of the present disclosure.

FIG. 3 illustrates an example of a wireless communications system that supports methods for automatic gain control in accordance with one or more aspects of the present disclosure.

FIG. 4 illustrates examples of resource configurations that support methods for automatic gain control in accordance with one or more aspects of the present disclosure.

FIG. 5 illustrates an example of a resource configuration that supports methods for automatic gain control in accordance with one or more aspects of the present disclosure.

FIG. 6 illustrates an example of a process flow that supports methods for automatic gain control in accordance with one or more aspects of the present disclosure.

FIGS. 7 and 8 illustrate block diagrams of devices that support methods for automatic gain control in accordance with one or more aspects of the present disclosure.

FIG. 9 illustrates a block diagram of a communications manager that supports methods for automatic gain control in accordance with one or more aspects of the present disclosure.

FIG. 10 illustrates a diagram of a system including a device that supports methods for automatic gain control in accordance with one or more aspects of the present disclosure.

FIGS. 11 through 14 illustrate flowcharts showing methods that support methods for automatic gain control in accordance with one or more aspects of the present disclosure.

### DETAILED DESCRIPTION

Some wireless communication systems may support multiple types of resource configurations (e.g., slot-based resource configurations, subslot-based resource configurations). Accordingly, some network devices may be configured to communicate using slot-based resources, subslot based resources (e.g., mini-slots), or both. In such cases, a network device (e.g., a user equipment (UE)) may receive both slot-based communications and subslot-based communications. Additionally, or alternatively, some subslot-based communications may be received within a slot or may otherwise overlap in time with slot-based communications. However, a UE may only be configured to perform automatic gain control (AGC) operations once per slot (e.g., during a first symbol period of a slot), which may present challenges if subslot-based communications are received during the slot. For example, a UE may be unable to adjust gain within a slot to accommodate for subslot-based communications, which may have a different received power when compared to slot-based communications.

In accordance with aspects of the present disclosure, a UE may perform AGC operations (e.g., AGC procedures) multiple times within a slot (e.g., to determine one or more gain states for receiving communications). For example, a UE may receive control signaling (e.g., from a network entity, from a different UE) indicating a parameter (e.g., an AGC parameter), which may specify that AGC (e.g., a second instance of AGC) should be performed at a first symbol period (e.g., a beginning symbol period) of a mini-slot. In some other cases, a UE may not receive the control signaling and may instead perform an energy detection operation to determine whether it should perform a second instance of AGC during a slot. The energy detection operation may be for detecting whether subslot-based communications are being transmitted by other UEs. Additionally, or alternatively, a UE that transmits subslot-based communications may determine to reduce gain for or otherwise refrain from transmitting the subslot-based communications if the UE detects slot-based communications within a specific frequency range.

Aspects of the disclosure are initially described in the context of wireless communications systems. Aspects of the disclosure are further illustrated by and described with reference to resource configurations, a process flow, apparatus diagrams, system diagrams, and flowcharts that relate to methods for automatic gain control.

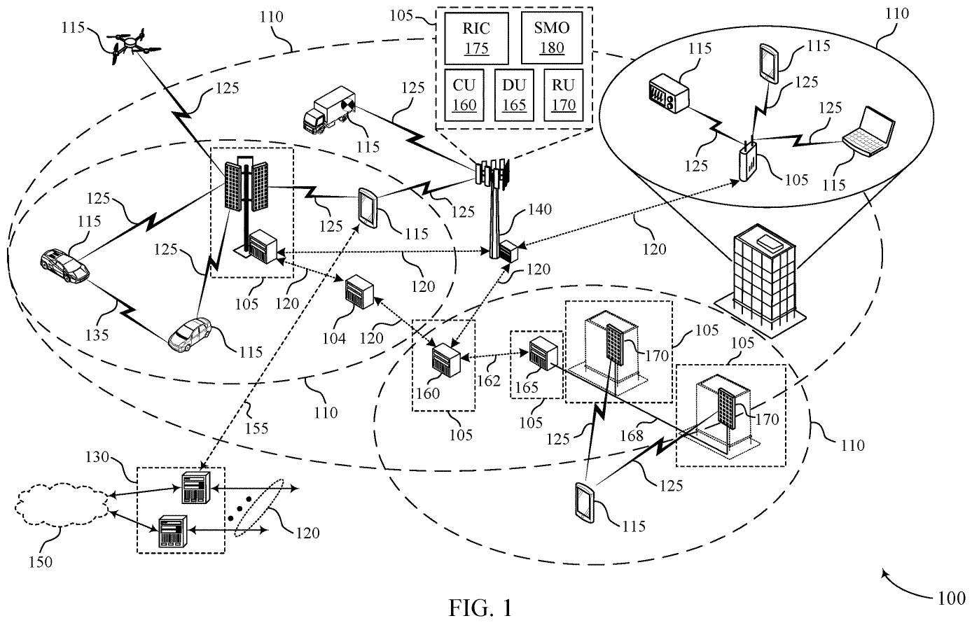

FIG. 1 illustrates an example of a wireless communications system 100 that supports methods for automatic gain control in accordance with one or more aspects of the present disclosure. The wireless communications system 100 may include one or more network entities 105, one or more UEs 115, and a core network 130. In some examples, the wireless communications system 100 may be a Long Term Evolution (LTE) network, an LTE-Advanced (LTE-A) network, an LTE-A Pro network, a New Radio (NR) network, or a network operating in accordance with other systems and radio technologies, including future systems and radio technologies not explicitly mentioned herein.

The network entities 105 may be dispersed throughout a geographic area to form the wireless communications system 100 and may include devices in different forms or having different capabilities. In various examples, a network entity 105 may be referred to as a network element, a mobility element, a radio access network (RAN) node, or network equipment, among other nomenclature. In some examples, network entities 105 and UEs 115 may wirelessly communicate via one or more communication links 125 (e.g., a radio frequency (RF) access link). For example, a network entity 105 may support a coverage area 110 (e.g., a geographic coverage area) over which the UEs 115 and the network entity 105 may establish one or more communication links 125. The coverage area 110 may be an example of a geographic area over which a network entity 105 and a UE 115 may support the communication of signals according to one or more radio access technologies (RATs).

The UEs 115 may be dispersed throughout a coverage area 110 of the wireless communications system 100, and each UE 115 may be stationary, or mobile, or both at different times. The UEs 115 may be devices in different forms or having different capabilities. Some example UEs 115 are illustrated in FIG. 1. The UEs 115 described herein may be capable of supporting communications with various types of devices, such as other UEs 115 or network entities 105, as shown in FIG. 1.

As described herein, a node of the wireless communications system 100, which may be referred to as a network node, or a wireless node, may be a network entity 105 (e.g., any network entity described herein), a UE 115 (e.g., any UE described herein), a network controller, an apparatus, a device, a computing system, one or more components, or another suitable processing entity configured to perform any of the techniques described herein. For example, a node may be a UE 115. As another example, a node may be a network entity 105. As another example, a first node may be configured to communicate with a second node or a third node. In one aspect of this example, the first node may be a UE 115, the second node may be a network entity 105, and the third node may be a UE 115. In another aspect of this example, the first node may be a UE 115, the second node may be a network entity 105, and the third node may be a network entity 105. In yet other aspects of this example, the first, second, and third nodes may be different relative to these examples. Similarly, reference to a UE 115, network entity 105, apparatus, device, computing system, or the like may include disclosure of the UE 115, network entity 105, apparatus, device, computing system, or the like being a node. For example, disclosure that a UE 115 is configured to receive information from a network entity 105 also discloses that a first node is configured to receive information from a second node.

In some examples, network entities 105 may communicate with the core network 130, or with one another, or both. For example, network entities 105 may communicate with the core network 130 via one or more backhaul communication links 120 (e.g., in accordance with an S1, N2, N3, or other interface protocol). In some examples, network entities 105 may communicate with one another via a backhaul communication link 120 (e.g., in accordance with an X2, Xn, or other interface protocol) either directly (e.g., directly between network entities 105) or indirectly (e.g., via a core network 130). In some examples, network entities 105 may communicate with one another via a midhaul communication link 162 (e.g., in accordance with a midhaul interface protocol) or a fronthaul communication link 168 (e.g., in accordance with a fronthaul interface protocol), or any combination thereof. The backhaul communication links 120, midhaul communication links 162, or fronthaul communication links 168 may be or include one or more wired links (e.g., an electrical link, an optical fiber link), one or more wireless links (e.g., a radio link, a wireless optical link), among other examples or various combinations thereof. A UE 115 may communicate with the core network 130 via a communication link 155.

One or more of the network entities 105 described herein may include or may be referred to as a base station 140 (e.g., a base transceiver station, a radio base station, an NR base station, an access point, a radio transceiver, a NodeB, an eNodeB (eNB), a next-generation NodeB or a giga-NodeB (either of which may be referred to as a gNB), a 5G NB, a next-generation eNB (ng-eNB), a Home NodeB, a Home eNodeB, or other suitable terminology). In some examples, a network entity 105 (e.g., a base station 140) may be implemented in an aggregated (e.g., monolithic, standalone) base station architecture, which may be configured to utilize a protocol stack that is physically or logically integrated within a single network entity 105 (e.g., a single RAN node, such as a base station 140).

In some examples, a network entity 105 may be implemented in a disaggregated architecture (e.g., a disaggregated base station architecture, a disaggregated RAN architecture), which may be configured to utilize a protocol stack that is physically or logically distributed among two or more network entities 105, such as an integrated access backhaul (IAB) network, an open RAN (O-RAN) (e.g., a network configuration sponsored by the O-RAN Alliance), or a virtualized RAN (vRAN) (e.g., a cloud RAN (C-RAN)). For example, a network entity 105 may include one or more of a central unit (CU) 160, a distributed unit (DU) 165, a radio unit (RU) 170, a RAN Intelligent Controller (RIC) 175 (e.g., a Near-Real Time RIC (Near-RT RIC), a Non-Real Time RIC (Non-RT RIC)), a Service Management and Orchestration (SMO) 180 system, or any combination thereof. An RU 170 may also be referred to as a radio head, a smart radio head, a remote radio head (RRH), a remote radio unit (RRU), or a transmission reception point (TRP). One or more components of the network entities 105 in a disaggregated RAN architecture may be co-located, or one or more components of the network entities 105 may be located in distributed locations (e.g., separate physical locations). In some examples, one or more network entities 105 of a disaggregated RAN architecture may be implemented as virtual units (e.g., a virtual CU (VCU), a virtual DU (VDU), a virtual RU (VRU)).

The split of functionality between a CU 160, a DU 165, and an RU 170 is flexible and may support different functionalities depending on which functions (e.g., network layer functions, protocol layer functions, baseband functions, RF functions, and any combinations thereof) are performed at a CU 160, a DU 165, or an RU 170. For example, a functional split of a protocol stack may be employed between a CU 160 and a DU 165 such that the CU 160 may support one or more layers of the protocol stack and the DU 165 may support one or more different layers of the protocol stack. In some examples, the CU 160 may host upper protocol layer (e.g., layer 3 (L3), layer 2 (L2)) functionality and signaling (e.g., Radio Resource Control (RRC), service data adaption protocol (SDAP), Packet Data Convergence Protocol (PDCP)). The CU 160 may be connected to one or more DUs 165 or RUs 170, and the one or more DUs 165 or RUs 170 may host lower protocol layers, such as layer 1 (L1) (e.g., physical (PHY) layer) or L2 (e.g., radio link control (RLC) layer, medium access control (MAC) layer) functionality and signaling, and may each be at least partially controlled by the CU 160. Additionally, or alternatively, a functional split of the protocol stack may be employed between a DU 165 and an RU 170 such that the DU 165 may support one or more layers of the protocol stack and the RU 170 may support one or more different layers of the protocol stack. The DU 165 may support one or multiple different cells (e.g., via one or more RUs 170). In some cases, a functional split between a CU 160 and a DU 165, or between a DU 165 and an RU 170 may be within a protocol layer (e.g., some functions for a protocol layer may be performed by one of a CU 160, a DU 165, or an RU 170, while other functions of the protocol layer are performed by a different one of the CU 160, the DU 165, or the RU 170). A CU 160 may be functionally split further into CU control plane (CU-CP) and CU user plane (CU-UP) functions. A CU 160 may be connected to one or more DUs 165 via a midhaul communication link 162 (e.g., F1, F1-c, F1-u), and a DU 165 may be connected to one or more RUs 170 via a fronthaul communication link 168 (e.g., open fronthaul (FH) interface). In some examples, a midhaul communication link 162 or a fronthaul communication link 168 may be implemented in accordance with an interface (e.g., a channel) between layers of a protocol stack supported by respective network entities 105 that are in communication via such communication links.

In wireless communications systems (e.g., wireless communications system 100), infrastructure and spectral resources for radio access may support wireless backhaul link capabilities to supplement wired backhaul connections, providing an IAB network architecture (e.g., to a core network 130). In some cases, in an IAB network, one or more network entities 105 (e.g., IAB nodes 104) may be partially controlled by each other. One or more IAB nodes 104 may be referred to as a donor entity or an IAB donor. One or more DUs 165 or one or more RUs 170 may be partially controlled by one or more CUs 160 associated with a donor network entity 105 (e.g., a donor base station 140). The one or more donor network entities 105 (e.g., IAB donors) may be in communication with one or more additional network entities 105 (e.g., IAB nodes 104) via supported access and backhaul links (e.g., backhaul communication links 120). IAB nodes 104 may include an IAB mobile termination (IAB-MT) controlled (e.g., scheduled) by DUs 165 of a coupled IAB donor. An IAB-MT may include an independent set of antennas for relay of communications with UEs 115, or may share the same antennas (e.g., of an RU 170) of an IAB node 104 used for access via the DU 165 of the IAB node 104 (e.g., referred to as virtual IAB-MT (vIAB-MT)). In some examples, the IAB nodes 104 may include DUs 165 that support communication links with additional entities (e.g., IAB nodes 104, UEs 115) within the relay chain or configuration of the access network (e.g., downstream). In such cases, one or more components of the disaggregated RAN architecture (e.g., one or more IAB nodes 104 or components of IAB nodes 104) may be configured to operate according to the techniques described herein.

In the case of the techniques described herein applied in the context of a disaggregated RAN architecture, one or more components of the disaggregated RAN architecture may be configured to support methods for automatic gain control as described herein. For example, some operations described as being performed by a UE 115 or a network entity 105 (e.g., a base station 140) may additionally, or alternatively, be performed by one or more components of the disaggregated RAN architecture (e.g., IAB nodes 104, DUs 165, CUs 160, RUs 170, RIC 175, SMO 180).

A UE 115 may include or may be referred to as a mobile device, a wireless device, a remote device, a handheld device, or a subscriber device, or some other suitable terminology, where the “device” may also be referred to as a unit, a station, a terminal, or a client, among other examples. A UE 115 may also include or may be referred to as a personal electronic device such as a cellular phone, a personal digital assistant (PDA), a tablet computer, a laptop computer, or a personal computer. In some examples, a UE 115 may include or be referred to as a wireless local loop (WLL) station, an Internet of Things (IoT) device, an Internet of Everything (IoE) device, or a machine type communications (MTC) device, among other examples, which may be implemented in various objects such as appliances, or vehicles, meters, among other examples.

The UEs 115 described herein may be able to communicate with various types of devices, such as other UEs 115 that may sometimes act as relays as well as the network entities 105 and the network equipment including macro eNBs or gNBs, small cell eNBs or gNBs, or relay base stations, among other examples, as shown in FIG. 1.

The UEs 115 and the network entities 105 may wirelessly communicate with one another via one or more communication links 125 (e.g., an access link) using resources associated with one or more carriers. The term “carrier” may refer to a set of RF spectrum resources having a defined physical layer structure for supporting the communication links 125. For example, a carrier used for a communication link 125 may include a portion of a RF spectrum band (e.g., a bandwidth part (BWP)) that is operated according to one or more physical layer channels for a given radio access technology (e.g., LTE, LTE-A, LTE-A Pro, NR). Each physical layer channel may carry acquisition signaling (e.g., synchronization signals, system information), control signaling that coordinates operation for the carrier, user data, or other signaling. The wireless communications system 100 may support communication with a UE 115 using carrier aggregation or multi-carrier operation. A UE 115 may be configured with multiple downlink component carriers and one or more uplink component carriers according to a carrier aggregation configuration. Carrier aggregation may be used with both frequency division duplexing (FDD) and time division duplexing (TDD) component carriers. Communication between a network entity 105 and other devices may refer to communication between the devices and any portion (e.g., entity, sub-entity) of a network entity 105. For example, the terms “transmitting,” “receiving,” or “communicating,” when referring to a network entity 105, may refer to any portion of a network entity 105 (e.g., a base station 140, a CU 160, a DU 165, a RU 170) of a RAN communicating with another device (e.g., directly or via one or more other network entities 105).

Signal waveforms transmitted via a carrier may be made up of multiple subcarriers (e.g., using multi-carrier modulation (MCM) techniques such as orthogonal frequency division multiplexing (OFDM) or discrete Fourier transform spread OFDM (DFT-S-OFDM)). In a system employing MCM techniques, a resource element may refer to resources of one symbol period (e.g., a duration of one modulation symbol) and one subcarrier, in which case the symbol period and subcarrier spacing may be inversely related. The quantity of bits carried by each resource element may depend on the modulation scheme (e.g., the order of the modulation scheme, the coding rate of the modulation scheme, or both), such that a relatively higher quantity of resource elements (e.g., in a transmission duration) and a relatively higher order of a modulation scheme may correspond to a relatively higher rate of communication. A wireless communications resource may refer to a combination of an RF spectrum resource, a time resource, and a spatial resource (e.g., a spatial layer, a beam), and the use of multiple spatial resources may increase the data rate or data integrity for communications with a UE 115.

The time intervals for the network entities 105 or the UEs 115 may be expressed in multiples of a basic time unit which may, for example, refer to a sampling period of Tₛ=1/(Δfₘₐₓ·N_{f}) seconds, for which Δfₘₐₓ may represent a supported subcarrier spacing, and N_{f} may represent a supported discrete Fourier transform (DFT) size. Time intervals of a communications resource may be organized according to radio frames each having a specified duration (e.g., 10 milliseconds (ms)). Each radio frame may be identified by a system frame number (SFN) (e.g., ranging from 0 to 1023).

Each frame may include multiple consecutively-numbered subframes or slots, and each subframe or slot may have the same duration. In some examples, a frame may be divided (e.g., in the time domain) into subframes, and each subframe may be further divided into a quantity of slots. Alternatively, each frame may include a variable quantity of slots, and the quantity of slots may depend on subcarrier spacing. Each slot may include a quantity of symbol periods (e.g., depending on the length of the cyclic prefix prepended to each symbol period). In some wireless communications systems 100, a slot may further be divided into multiple mini-slots associated with one or more symbols. Excluding the cyclic prefix, each symbol period may be associated with one or more (e.g., N_{f}) sampling periods. The duration of a symbol period may depend on the subcarrier spacing or frequency band of operation.

A subframe, a slot, a mini-slot, or a symbol may be the smallest scheduling unit (e.g., in the time domain) of the wireless communications system 100 and may be referred to as a transmission time interval (TTI). In some examples, the TTI duration (e.g., a quantity of symbol periods in a TTI) may be variable. Additionally, or alternatively, the smallest scheduling unit of the wireless communications system 100 may be dynamically selected (e.g., in bursts of shortened TTIs (sTTIs)).

Physical channels may be multiplexed for communication using a carrier according to various techniques. A physical control channel and a physical data channel may be multiplexed for signaling via a downlink carrier, for example, using one or more of time division multiplexing (TDM) techniques, frequency division multiplexing (FDM) techniques, or hybrid TDM-FDM techniques. A control region (e.g., a control resource set (CORESET)) for a physical control channel may be defined by a set of symbol periods and may extend across the system bandwidth or a subset of the system bandwidth of the carrier. One or more control regions (e.g., CORESETs) may be configured for a set of the UEs 115. For example, one or more of the UEs 115 may monitor or search control regions for control information according to one or more search space sets, and each search space set may include one or multiple control channel candidates in one or more aggregation levels arranged in a cascaded manner. An aggregation level for a control channel candidate may refer to an amount of control channel resources (e.g., control channel elements (CCEs)) associated with encoded information for a control information format having a given payload size. Search space sets may include common search space sets configured for sending control information to multiple UEs 115 and UE-specific search space sets for sending control information to a specific UE 115.

In some examples, a network entity 105 (e.g., a base station 140, an RU 170) may be movable and therefore provide communication coverage for a moving coverage area 110. In some examples, different coverage areas 110 associated with different technologies may overlap, but the different coverage areas 110 may be supported by the same network entity 105. In some other examples, the overlapping coverage areas 110 associated with different technologies may be supported by different network entities 105. The wireless communications system 100 may include, for example, a heterogeneous network in which different types of the network entities 105 provide coverage for various coverage areas 110 using the same or different radio access technologies.

The wireless communications system 100 may be configured to support ultra-reliable communications or low-latency communications, or various combinations thereof. For example, the wireless communications system 100 may be configured to support ultra-reliable low-latency communications (URLLC). The UEs 115 may be designed to support ultra-reliable, low-latency, or critical functions. Ultra-reliable communications may include private communication or group communication and may be supported by one or more services such as push-to-talk, video, or data. Support for ultra-reliable, low-latency functions may include prioritization of services, and such services may be used for public safety or general commercial applications. The terms ultra-reliable, low-latency, and ultra-reliable low-latency may be used interchangeably herein.

In some examples, a UE 115 may be configured to support communicating directly with other UEs 115 via a device-to-device (D2D) communication link 135 (e.g., in accordance with a peer-to-peer (P2P), D2D, or sidelink protocol). In some examples, one or more UEs 115 of a group that are performing D2D communications may be within the coverage area 110 of a network entity 105 (e.g., a base station 140, an RU 170), which may support aspects of such D2D communications being configured by (e.g., scheduled by) the network entity 105. In some examples, one or more UEs 115 of such a group may be outside the coverage area 110 of a network entity 105 or may be otherwise unable to or not configured to receive transmissions from a network entity 105. In some examples, groups of the UEs 115 communicating via D2D communications may support a one-to-many (1:M) system in which each UE 115 transmits to each of the other UEs 115 in the group. In some examples, a network entity 105 may facilitate the scheduling of resources for D2D communications. In some other examples, D2D communications may be carried out between the UEs 115 without an involvement of a network entity 105.

In some systems, a D2D communication link 135 may be an example of a communication channel, such as a sidelink communication channel, between vehicles (e.g., UEs 115). In some examples, vehicles may communicate using vehicle-to-everything (V2X) communications, vehicle-to-vehicle (V2V) communications, or some combination of these. A vehicle may signal information related to traffic conditions, signal scheduling, weather, safety, emergencies, or any other information relevant to a V2X system. In some examples, vehicles in a V2X system may communicate with roadside infrastructure, such as roadside units, or with the network via one or more network nodes (e.g., network entities 105, base stations 140, RUs 170) using vehicle-to-network (V2N) communications, or with both.

The core network 130 may provide user authentication, access authorization, tracking, Internet Protocol (IP) connectivity, and other access, routing, or mobility functions. The core network 130 may be an evolved packet core (EPC) or 5G core (5GC), which may include at least one control plane entity that manages access and mobility (e.g., a mobility management entity (MME), an access and mobility management function (AMF)) and at least one user plane entity that routes packets or interconnects to external networks (e.g., a serving gateway (S-GW), a Packet Data Network (PDN) gateway (P-GW), or a user plane function (UPF)). The control plane entity may manage non-access stratum (NAS) functions such as mobility, authentication, and bearer management for the UEs 115 served by the network entities 105 (e.g., base stations 140) associated with the core network 130. User IP packets may be transferred through the user plane entity, which may provide IP address allocation as well as other functions. The user plane entity may be connected to IP services 150 for one or more network operators. The IP services 150 may include access to the Internet, Intranet(s), an IP Multimedia Subsystem (IMS), or a Packet-Switched Streaming Service.

The wireless communications system 100 may operate using one or more frequency bands, which may be in the range of 300 megahertz (MHz) to 300 gigahertz (GHz). Generally, the region from 300 MHz to 3 GHz is known as the ultra-high frequency (UHF) region or decimeter band because the wavelengths range from approximately one decimeter to one meter in length. UHF waves may be blocked or redirected by buildings and environmental features, which may be referred to as clusters, but the waves may penetrate structures sufficiently for a macro cell to provide service to the UEs 115 located indoors. Communications using UHF waves may be associated with smaller antennas and shorter ranges (e.g., less than 100 kilometers) compared to communications using the smaller frequencies and longer waves of the high frequency (HF) or very high frequency (VHF) portion of the spectrum below 300 MHz.

The wireless communications system 100 may utilize both licensed and unlicensed RF spectrum bands. For example, the wireless communications system 100 may employ License Assisted Access (LAA), LTE-Unlicensed (LTE-U) radio access technology, or NR technology using an unlicensed band such as the 5 GHz industrial, scientific, and medical (ISM) band. While operating using unlicensed RF spectrum bands, devices such as the network entities 105 and the UEs 115 may employ carrier sensing for collision detection and avoidance. In some examples, operations using unlicensed bands may be based on a carrier aggregation configuration in conjunction with component carriers operating using a licensed band (e.g., LAA). Operations using unlicensed spectrum may include downlink transmissions, uplink transmissions, P2P transmissions, or D2D transmissions, among other examples.

A network entity 105 (e.g., a base station 140, an RU 170) or a UE 115 may be equipped with multiple antennas, which may be used to employ techniques such as transmit diversity, receive diversity, multiple-input multiple-output (MIMO) communications, or beamforming. The antennas of a network entity 105 or a UE 115 may be located within one or more antenna arrays or antenna panels, which may support MIMO operations or transmit or receive beamforming. For example, one or more base station antennas or antenna arrays may be co-located at an antenna assembly, such as an antenna tower. In some examples, antennas or antenna arrays associated with a network entity 105 may be located at diverse geographic locations. A network entity 105 may include an antenna array with a set of rows and columns of antenna ports that the network entity 105 may use to support beamforming of communications with a UE 115. Likewise, a UE 115 may include one or more antenna arrays that may support various MIMO or beamforming operations. Additionally, or alternatively, an antenna panel may support RF beamforming for a signal transmitted via an antenna port.

Beamforming, which may also be referred to as spatial filtering, directional transmission, or directional reception, is a signal processing technique that may be used at a transmitting device or a receiving device (e.g., a network entity 105, a UE 115) to shape or steer an antenna beam (e.g., a transmit beam, a receive beam) along a spatial path between the transmitting device and the receiving device. Beamforming may be achieved by combining the signals communicated via antenna elements of an antenna array such that some signals propagating along particular orientations with respect to an antenna array experience constructive interference while others experience destructive interference. The adjustment of signals communicated via the antenna elements may include a transmitting device or a receiving device applying amplitude offsets, phase offsets, or both to signals carried via the antenna elements associated with the device. The adjustments associated with each of the antenna elements may be defined by a beamforming weight set associated with a particular orientation (e.g., with respect to the antenna array of the transmitting device or receiving device, or with respect to some other orientation).

The wireless communications system 100 may be a packet-based network that operates according to a layered protocol stack. In the user plane, communications at the bearer or PDCP layer may be IP-based. An RLC layer may perform packet segmentation and reassembly to communicate via logical channels. A MAC layer may perform priority handling and multiplexing of logical channels into transport channels. The MAC layer also may implement error detection techniques, error correction techniques, or both to support retransmissions to improve link efficiency. In the control plane, an RRC layer may provide establishment, configuration, and maintenance of an RRC connection between a UE 115 and a network entity 105 or a core network 130 supporting radio bearers for user plane data. A PHY layer may map transport channels to physical channels.

In accordance with aspects of the present disclosure, a UE 115 may perform AGC operations (e.g., AGC procedures) multiple times within a slot. For example, a UE 115 may receive control signaling (e.g., from a network entity 105, from a different UE 115) indicating a parameter (e.g., an AGC parameter), which may specify that AGC (e.g., a second instance of AGC) should be performed at a first symbol period (e.g., a beginning symbol period) of a mini-slot. In some other cases, a UE 115 may not receive the control signaling and may instead perform an energy detection operation to determine whether it should perform a second instance of AGC during a slot. The energy detection operation may be for detecting whether subslot-based communications are being transmitted by other UEs 115. Additionally, or alternatively, a UE 115 that transmits subslot-based communications may determine to reduce gain for or otherwise refrain from transmitting the subslot-based communications if the UE 115 detects slot-based communications within a specific frequency range.

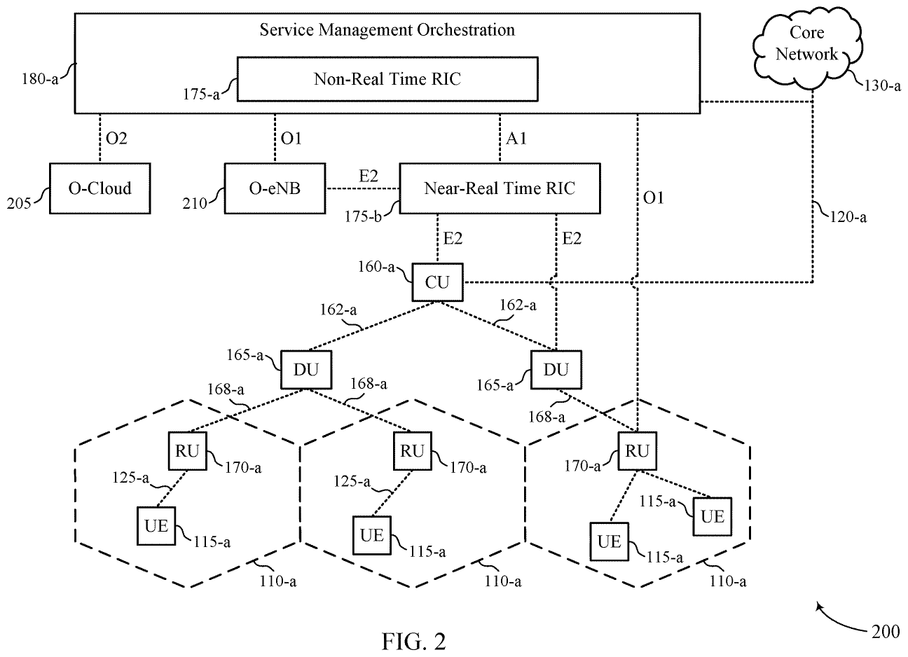

FIG. 2 illustrates an example of a network architecture 200 (e.g., a disaggregated base station architecture, a disaggregated RAN architecture) that supports methods for automatic gain control in accordance with one or more aspects of the present disclosure. The network architecture 200 may illustrate an example for implementing one or more aspects of the wireless communications system 100. The network architecture 200 may include one or more CUs 160-a that may communicate directly with a core network 130-a via a backhaul communication link 120-a, or indirectly with the core network 130-a through one or more disaggregated network entities 105 (e.g., a Near-RT RIC 175-b via an E2 link, or a Non-RT RIC 175-a associated with an SMO 180-a (e.g., an SMO Framework), or both). A CU 160-a may communicate with one or more DUs 165-a via respective midhaul communication links 162-a (e.g., an F1 interface). The DUs 165-a may communicate with one or more RUs 170-a via respective fronthaul communication links 168-a. The RUs 170-a may be associated with respective coverage areas 110-a and may communicate with UEs 115-a via one or more communication links 125-a. In some implementations, a UE 115-a may be simultaneously served by multiple RUs 170-a.

Each of the network entities 105 of the network architecture 200 (e.g., CUs 160-a, DUs 165-a, RUs 170-a, Non-RT RICs 175-a, Near-RT RICs 175-b, SMOs 180-a, Open Clouds (O-Clouds) 205, Open eNBs (O-eNBs) 210) may include one or more interfaces or may be coupled with one or more interfaces configured to receive or transmit signals (e.g., data, information) via a wired or wireless transmission medium. Each network entity 105, or an associated processor (e.g., controller) providing instructions to an interface of the network entity 105, may be configured to communicate with one or more of the other network entities 105 via the transmission medium. For example, the network entities 105 may include a wired interface configured to receive or transmit signals over a wired transmission medium to one or more of the other network entities 105. Additionally, or alternatively, the network entities 105 may include a wireless interface, which may include a receiver, a transmitter, or transceiver (e.g., an RF transceiver) configured to receive or transmit signals, or both, over a wireless transmission medium to one or more of the other network entities 105.

In some examples, a CU 160-a may host one or more higher layer control functions. Such control functions may include RRC, PDCP, SDAP, or the like. Each control function may be implemented with an interface configured to communicate signals with other control functions hosted by the CU 160-a. A CU 160-a may be configured to handle user plane functionality (e.g., CU-UP), control plane functionality (e.g., CU-CP), or a combination thereof. In some examples, a CU 160-a may be logically split into one or more CU-UP units and one or more CU-CP units. A CU-UP unit may communicate bidirectionally with the CU-CP unit via an interface, such as an E1 interface when implemented in an O-RAN configuration. A CU 160-a may be implemented to communicate with a DU 165-a, as necessary, for network control and signaling.

A DU 165-a may correspond to a logical unit that includes one or more functions (e.g., base station functions, RAN functions) to control the operation of one or more RUs 170-a. In some examples, a DU 165-a may host, at least partially, one or more of an RLC layer, a MAC layer, and one or more aspects of a PHY layer (e.g., a high PHY layer, such as modules for FEC encoding and decoding, scrambling, modulation and demodulation, or the like) depending, at least in part, on a functional split, such as those defined by the 3rd Generation Partnership Project (3GPP). In some examples, a DU 165-a may further host one or more low PHY layers. Each layer may be implemented with an interface configured to communicate signals with other layers hosted by the DU 165-a, or with control functions hosted by a CU 160-a.

In some examples, lower-layer functionality may be implemented by one or more RUs 170-a. For example, an RU 170-a, controlled by a DU 165-a, may correspond to a logical node that hosts RF processing functions, or low-PHY layer functions (e.g., performing fast Fourier transform (FFT), inverse FFT (iFFT), digital beamforming, physical random access channel (PRACH) extraction and filtering, or the like), or both, based at least in part on the functional split, such as a lower-layer functional split. In such an architecture, an RU 170-a may be implemented to handle over the air (OTA) communication with one or more UEs 115-a. In some implementations, real-time and non-real-time aspects of control and user plane communication with the RU(s) 170-a may be controlled by the corresponding DU 165-a. In some examples, such a configuration may enable a DU 165-a and a CU 160-a to be implemented in a cloud-based RAN architecture, such as a vRAN architecture.

The SMO 180-a may be configured to support RAN deployment and provisioning of non-virtualized and virtualized network entities 105. For non-virtualized network entities 105, the SMO 180-a may be configured to support the deployment of dedicated physical resources for RAN coverage requirements which may be managed via an operations and maintenance interface (e.g., an O1 interface). For virtualized network entities 105, the SMO 180-a may be configured to interact with a cloud computing platform (e.g., an O-Cloud 205) to perform network entity life cycle management (e.g., to instantiate virtualized network entities 105) via a cloud computing platform interface (e.g., an O2 interface). Such virtualized network entities 105 can include, but are not limited to, CUs 160-a, DUs 165-a, RUs 170-a, and Near-RT RICs 175-b. In some implementations, the SMO 180-a may communicate with components configured in accordance with a 4G RAN (e.g., via an O1 interface). Additionally, or alternatively, in some implementations, the SMO 180-a may communicate directly with one or more RUs 170-a via an O1 interface. The SMO 180-a also may include a Non-RT RIC 175-a configured to support functionality of the SMO 180-a.

The Non-RT RIC 175-a may be configured to include a logical function that enables non-real-time control and optimization of RAN elements and resources, Artificial Intelligence (AI) or Machine Learning (ML) workflows including model training and updates, or policy-based guidance of applications/features in the Near-RT RIC 175-b. The Non-RT RIC 175-a may be coupled to or communicate with (e.g., via an AI interface) the Near-RT RIC 175-b. The Near-RT RIC 175-b may be configured to include a logical function that enables near-real-time control and optimization of RAN elements and resources via data collection and actions over an interface (e.g., via an E2 interface) connecting one or more CUs 160-a, one or more DUs 165-a, or both, as well as an O-eNB 210, with the Near-RT RIC 175-b.

In some examples, to generate AI/ML models to be deployed in the Near-RT RIC 175-b, the Non-RT RIC 175-a may receive parameters or external enrichment information from external servers. Such information may be utilized by the Near-RT RIC 175-b and may be received at the SMO 180-a or the Non-RT RIC 175-a from non-network data sources or from network functions. In some examples, the Non-RT RIC 175-a or the Near-RT RIC 175-b may be configured to tune RAN behavior or performance. For example, the Non-RT RIC 175-a may monitor long-term trends and patterns for performance and employ AI or ML models to perform corrective actions through the SMO 180-a (e.g., reconfiguration via 01) or via generation of RAN management policies (e.g., AI policies).

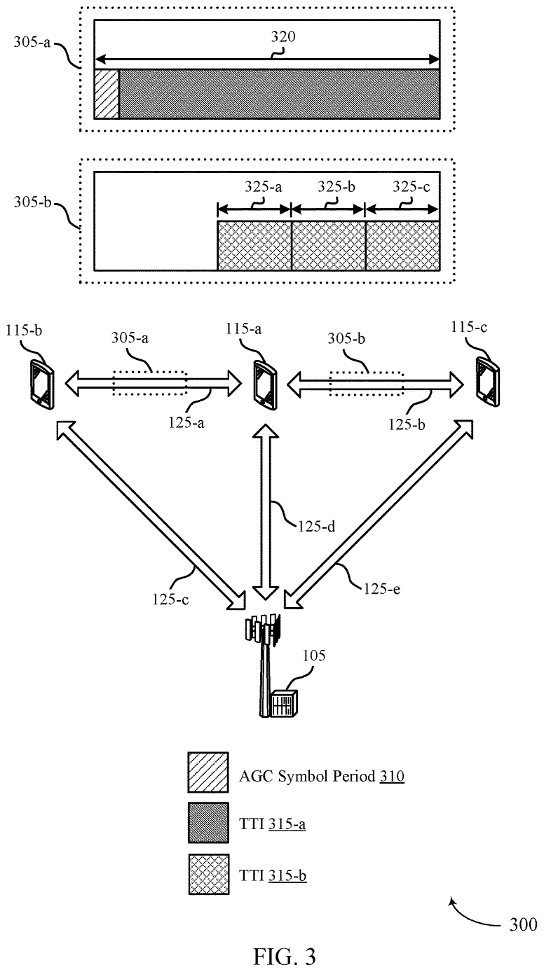

FIG. 3 illustrates an example of a wireless communications system 300 that supports methods for automatic gain control in accordance with one or more aspects of the present disclosure. The wireless communications system 300 may include a UE 115-a, a UE 115-b, a UE 115-c, and a network entity 105, which may be examples of corresponding UEs 115 and network entities 105 as described with reference to FIGS. 1 and 2. The wireless communications system 300 may also include one or more communication links 125, which may be examples of communication links 125 as described with reference to FIGS. 1 and 2.

A UE 115 may communicate directly with one or more other UEs 115. For example, the UE 115-a may establish a communication link 125-a with the UE 115-b and may perform sidelink communications via the communication link 125-a. Additionally, or alternatively, the UE 115-a may establish a communication link 125-b with the UE 115-c and may perform sidelink communications via the communication link 125-b. In some other cases, a UE 115 may perform communications (e.g., sidelink communications) without establishing a communication link 125-a. For example, the UE 115-c may transmit (e.g., broadcast) information, which may be received by the UE 115-a prior to the establishment of a communication link 125. Additionally, or alternatively, a UE 115 may receive communications as interference (e.g., where no communication link 125 is established).

Each UE 115 may also communicate with the network entity 105 (e.g., via respective communication links 125). In some cases, a UE 115 may be configured by a network entity 105. For example, a network entity 105 may transmit, to a UE 115, an indication of communication resources to be utilized by the UE 115 for communications (e.g., with other UEs 115, with the network entity 105). The indication of the communication resources may specify a communication resource pool, such as a slot-based resource pool 305-a, a subslot-based resource pool 305-b, or both. Accordingly, a UE 115 may determine a type of communication resources (e.g., slot-based resources, subslot-based resources) for communications based on the indication from the network entity 105. For example, a UE 115 may determinate a duration for TTIs 315 based on the indication, where the duration may correspond to or otherwise specify a type or duration of communication resources (e.g., slots 320, mini-slots 325). That is, the UE 115 may determine to perform communications using slot-based communication resources (e.g., using the slot-based resource pool 305-a) or communications using subslot-based communication resources (e.g., using the subslot-based resource pool 305-b).

A resource pool (e.g., a slot-based resource pool 305-a, a subslot-based resource pool 305-b) may include a quantity of communication resources, which may be configured according to a duration of a TTI 315. For example, a slot-based resource pool 305-a may include a quantity of slots 320, each slot 320 having a TTI 315-a (e.g., each slot 320 having a first duration). A subslot-based resource pool 305-b may include a quantity of mini-slots 325, each having a TTI 315-b (e.g., each mini-slot has a second duration, shorter than the first duration). As an illustrative example, a slot 320 may include four mini-slots, although other configurations may be utilized. For example, a slot 320 may include two mini-slots 325, three mini-slots 325, and so on. Similarly, as described herein, the TTI 315-a (e.g., a slot 320) may include any quantity of TTIs 315-b (e.g., mini-slots 325).

In some cases, a network device (e.g., a UE 115, a network entity 105) may transmit slot-based communications, subslot-based communications, or both (e.g., concurrently or at different times). Additionally, or alternatively, a network device may receive both slot-based communications and subslot-based communications (e.g., concurrently or at different times). For example, the UE 115-a may receive slot-based communications from the UE 115-b and subslot-based communications from the UE 115-c (e.g., concurrently, within a same slot 320, within a same TTI 315-a). Although FIG. 2 shows an illustrative example of the UE 115-b performing slot-based communications and the UE 115-c performing subslot-based communications, any network device as described herein may perform (e.g., transmit, receive) slot-based communications, subslot-based communications, or both.

A resource pool (e.g., a slot-based resource pool 305-a, a subslot-based resource pool 305-b) may include time-frequency resources for performing communications (e.g., symbol periods and resource blocks (RBs)). In some cases, communication resources included in two resource pools (e.g., the slot-based resource pool 305-a and the subslot-based resource pool 305-b) may occupy a same frequency band (e.g., a same set of RBs). In some other cases, communication resources included in two resource pools (e.g., the slot-based resource pool 305-a and the subslot-based resource pool 305-b) may occupy different frequency bands (e.g., a different set of RBs). That is, the slot-based resource pool 305-a and the subslot-based resource pool 305-b may not overlap in frequency.

As an illustrative example, a slot-based resource pool 305-a and a subslot-based resource pool 305-b (e.g., a mini-slot resource pool) may be configured (e.g., by a network entity 105) to be in a same frequency band. That is, the slot-based resource pool 305-a and the subslot-based resource pool 305-b may or may not overlap in frequency. In some cases, the UE 115-b may transmit information (e.g., one or more physical sidelink control channel (PSCCH) messages, one or more physical sidelink shared channel (PSSCH) messages) to the UE 115-a using one or more communication resources included in the slot-based resource pool 305-a. The UE 115-a may perform an AGC operation during an AGC symbol period 310 (e.g., during or after a beginning symbol period of a slot 320). Additionally, or alternatively, the UE 115-c may transmit information using one or more subslot-based communication resources (e.g., using mini-slots 325). For example, the UE 115-c may transmit one or more PSSCH messages during a slot 320 (e.g., in the middle of a slot 320). In some cases, the UE 115-c may transmit the one or more PSSCH messages to the UE 115-a or alternatively to a UE 115 (not shown) different from the UE 115-a, however, the UE 115-a may receive the one or more PSSCH messages (e.g., as interference or otherwise).

The UE 115-c may perform a listen-before-talk (LBT) operation prior to transmitting the information using the one or more subslot-based communications. The UE 115-c may perform the LBT operation for a frequency range (e.g., a frequency band), which may be the same or different from a frequency range for the one or more PSSCH messages (e.g., transmitted by the UE 115-c). The UE 115-c may determine to transmit the one or more PSSCH messages based on a result of the LBT operation. For example, if the UE 115-c detects communications in a frequency range, the UE 115-c may determine not to transmit communications in the frequency range. Accordingly, even if the UE 115-c detects slot-based communications from the UE 115-b in a first frequency range, the UE 115-c may still determine to transmit subslot-based communications in a second frequency range, where both the slot-based and subslot-based communications may be received by the UE 115-a.

If a slot-based resource pool 305-a and a subslot-based resource pool 305-b are in a same LBT sub-band (e.g., a same frequency range), an LBT operation may block a UE 115 that transmits information using the subslot-based resource pool 305-b from transmitting subslot-based communications (e.g., mini-slots 325) that overlap with slot-based communications. For example, the UE 115-c may determine not to transmit mini-slots 325 (e.g., during a slot 320) based on detecting slot-based communications in a same frequency band.

As part of an LBT operation, a UE 115 may determine if detected energy (e.g., from received communications) is above an energy detection (ED) threshold. For example, the UE 115-c may refrain from transmitting subslot-based communications if an ED threshold is exceeded (e.g., during the LBT operation). The ED threshold may be configured (e.g., preconfigured) based on a power class (e.g., for a UE 115) and based on a radio access technology (RAT) utilized by a UE 115. Additionally, or alternatively, the ED threshold may be configured based on a RAT for communications received by the UE 115. For example, the ED threshold may apply to both intra-RAT and inter-RAT communications (e.g., communications conforming to one or more protocols for a same RAT as a UE or a different RAT from a UE). In some cases, a UE 115 that utilizes a first RAT may perform an LBT operation to reduce or eliminate interference associated with full-slot sidelink communications using the first RAT and may discount or otherwise ignore intra-RAT communications (e.g., communications using RATs different from the first RAT).

If a slot-based resource pool 305-a and a subslot-based resource pool 305-b are in different sub-bands (e.g., different LBT sub-bands, different frequency ranges), an LBT operation may not block a UE 115 that transmits information using the subslot-based resource pool 305-b from transmitting subslot-based communications (e.g., mini-slots 325) that overlap with (e.g., in time) slot-based communications. For example, the UE 115-c may determine to transmit mini-slots 325 during a slot based on not detecting slot-based communications in a same frequency band. That is, the UE 115-c may determine to transmit subslot-based communications based on clearing an LBT operation. As a result, the UE 115-a may receive subslot-based communications from the UE 115-c (e.g., during a slot, during a TTI 315-a). However, in some cases, the UE 115-a may not be configured to adjust an AGC setting to account for receiving the subslot-based communications. For example, the UE 115-a may be configured to perform only one AGC operation during the AGC symbol period 310, which may occur during a first symbol period of a slot 320. As a result, the UE 115-a receiving both the subslot-based communications from the UE 115-c and slot-based communications from other UEs 115 may cause clipping to occur (e.g., if a combined received signal power for subslot-based communications and slot-based communications exceeds a threshold). For example, an interference threshold (e.g., interference margin) may be exceeded, which may result in clipping at an analog to digital converter of the UE 115-a.

In some cases, a slot 320 may include AGC symbol periods 310 for a full slot PSSCH transmission at a potential mini-slot starting symbol. A full slot receiver (e.g., a UE 115-a) may adjust its AGC at these AGC symbols (e.g., to determine one or more gain states for receiving communications). The problems of introducing additional AGC symbol periods 310 for full slot PSSCH transmissions are AGC symbol overhead and receiver phase discontinuity. For example, one or more middle AGC symbol periods 310 may not be used for PSSCH transmission even when there is no mini-slot transmission starting in the middle of a slot 320. Additionally, or alternatively, a low-noise amplifier (LNA) gain state change may involve a receiver filter change. Additionally, or alternatively, channel estimation (e.g., channel estimation results) across a middle AGC symbol period 310 may not be combined.

In accordance with one or more aspects of the present disclosure, a UE 115 may perform multiple AGC operations during a slot 320 (e.g., during a TTI 315-a). For example, in addition to performing a first AGC operation during a first symbol period of a slot 320 (e.g., to determine a first gain state for receiving a sidelink grant), the UE 115 may perform a second AGC operation during a second symbol period of the slot 320. In some cases, the second symbol period of the slot 320 for performing the second AGC operation may overlap with a first symbol period of a mini-slot 325 (e.g., a beginning symbol period for subslot-based communications). In such cases, a UE 115 may perform the second AGC operation based on an indication, which may be received from another UE 115 or a network entity 105. In some other cases, a UE 115 may not receive an indication to perform additional AGC operations and may instead perform an ED operation to determine whether to perform an AGC operation at a mini-slot 325 starting symbol (e.g., beginning symbol). Additionally, or alternatively, a UE 115 that transmits subslot-based communications (e.g., the UE 115-c) may monitor for slot-based communications and may determine to withhold (e.g., refrain from transmitting) subslot-based communications based on whether the UE 115 detects one or more full-slot transmissions within a frequency range (e.g., a preconfigured frequency range).

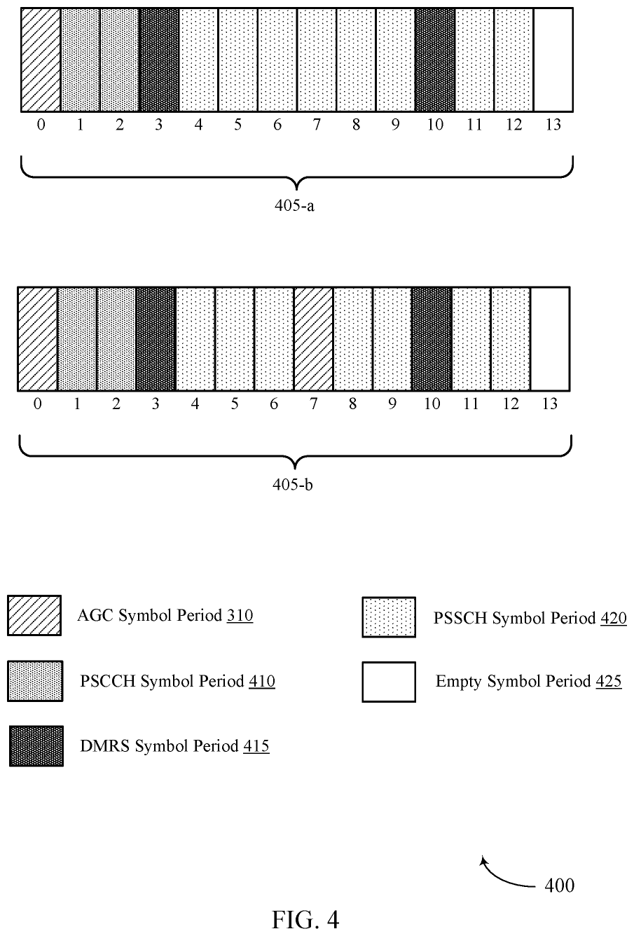

FIG. 4 illustrates an example of resource configurations 400 that support methods for automatic gain control in accordance with one or more aspects of the present disclosure. For example, the resource configurations 400 may include a slot 405-a and a slot 405-b, which may both be examples of a slot-based resource pool 305-a as described with reference to FIG. 2. A slot 405 may be implemented by one or more aspects of the wireless communication system 100, the network architecture 200, or the wireless communications system 300. For example, a network device, such as a UE 115 or a network entity 105 as described with reference to FIGS. 1-3, may communicate using one or more resources in a slot 405. A slot 405 may include one or more AGC symbol periods 310, one or more PSCCH symbol periods 410, one or more demodulation reference signal (DMRS) symbol periods 415, one or more PSSCH symbol periods 420, and one or more empty symbol periods 425 (e.g., one or more gaps, one or more gap symbol periods).

A network device may transmit or receive communications using one or more resources included in a slot 405. For example, a UE 115 may receive PSCCH signaling from another UE 115 during one or more PSCCH symbol periods 410 (e.g., symbol period 1, symbol period 2). The UE 115 may perform an adjustment for one or more AGC parameters (e.g., at the beginning of a PSCCH transmission, at the beginning of a PSSCH transmission). In some cases, the UE 115 may perform an AGC operation during a first symbol period of the slot 405-a (e.g., symbol period 0) and may refrain from performing additional AGC operations during a slot 405 (e.g., in accordance with the slot 405-a). In such cases, a first symbol period of the slot 405-a is assumed to be an AGC symbol period 310.

In some other cases, a UE 115 may adjust one or more AGC parameters one or multiple times within a slot 405 (e.g., at potential mini-slot starting symbols within the slot 405). That is, a UE 115 may perform multiple AGC operations within a slot 405, a first AGC operation being performed at a beginning symbol period of the slot 405 and a second being performed at an intermediate symbol period of the slot 405. In such cases, a UE 115 may perform AGC operations during one or more symbol periods dedicated to AGC operations (e.g., one or more AGC symbol periods 310) or may alternatively perform AGC operations during symbol periods not specifically reserved for AGC operations. For example, if only one AGC symbol period 310 is transmitted (e.g., to the UE 115), a PSSCH symbol period 410 (e.g., symbol period 7 of the slot 405-a) may be used for AGC operations. In such cases, one or more PSSCH symbol periods 420 may be punctured. In such cases, a PSSCH symbol period 420 or a portion of resources associated with the PSSCH symbol period 420 (e.g., a punctured portion of resources) may not be used for decoding. In some other cases, (e.g., where multiple AGC symbol periods 310 are transmitted), a UE 115 may perform AGC operations during each AGC symbol period 310 (e.g., in accordance with the slot 405-b).

A UE 115 may match AGC operations with a pattern for DMRS signaling (e.g., a pattern of DMRS symbol periods 415 in slot 405 indicated by network entity 105 or another UE 115). In some cases, slot 405-b may be divided into multiple segments (e.g., sets) of PSSCH symbol periods 420. For example, the slot 405-b may be described as including a first segment (e.g., including symbol periods 0 through 6) and a second segment (e.g., including symbol periods 7 through 13). In some cases, each segment may be referred to as a PSSCH segment or a segment of PSSCH symbol periods 420. Each segment of PSSCH symbol periods 420 may include at least one DMRS symbol period 415, which may be utilized for channel estimation. Additionally, or alternatively, each segment of PSSCH symbol periods 420 may begin with AGC adjustment (e.g., an AGC symbol period 310). In such cases, it may be advantageous to perform independent channel estimation in each segment of PSSCH symbol periods 420. For example, a slot 405 may be segmented by AGC symbol periods 310 and the UE 115 may perform channel estimation (e.g., independently) for each segment of the slot 405 (e.g., for each AGC symbol period 310).

Subslot-based communications may begin or otherwise occur during any symbol period of a slot 405. For example, a first symbol period (e.g., a candidate starting symbol period, a beginning symbol period) of a mini-slot may overlap with or partially overlap with a first symbol period of a slot 405 (e.g., symbol period 0) and a seventh symbol period of the slot 405 (e.g., symbol period 7). Although one illustrative example as described herein may refer to a seventh symbol period of a slot 405 overlapping with a starting symbol period (e.g., a candidate starting symbol) for a mini-slot, subslot-based communications may begin or overlap with any other symbol period of a slot 405. For example, multiple configurations for subslot-based communications may be possible, such as mini-slots having two symbol periods, mini-slots having three symbol periods, and so forth.

In some cases, a UE 115 may perform an AGC operation at each starting symbol for subslot-based communications (e.g., each mini-slot starting symbol, each candidate starting symbol). For example, a UE 115 may perform an AGC operation at an AGC symbol period 310 that coincides or otherwise overlaps with a first symbol period of a mini-slot. In such implementations, a UE 115 may perform independent (e.g., separate) channel estimation for each segment of a slot 405 (e.g., each set of PSSCH symbol periods 420 corresponding to a different mini-slot). Additionally, or alternatively, each segment of a slot 405 may include at least one DMRS symbol period 415. In some cases, a UE 115 may refrain from combining or extrapolating channel estimation for multiple segments of a slot 405 (e.g., multiple segments of PSSCH symbol periods 420) if a gain state (e.g., a low-noise amplifier (LNA) gain state) changes (e.g., across the multiple segments of the slot 405). For example, if an LNA gain state changes after a candidate starting symbol, the channel estimation cannot be combined or extrapolated from a previous (e.g., a first) PSSCH segment. Additionally, or alternatively, a UE 115 may perform an energy detection operation and may determine whether to perform one or more AGC operations based on a result of the energy detection operation.

In some cases, a slot 405 may include a DMRS symbol period 415 for each segment (e.g., each PSSCH segment). For example, the slot 405-b may include two segments, where each segment begins with an AGC symbol period 310. The first segment may include the symbol period 0 through the symbol period 6. The second segment may include the symbol period 7 through the symbol period 13. Where a slot 405 has two segments, each segment may include a DMRS symbol period 415. For example, the first segment may include a DMRS symbol period 415 (e.g., at symbol period 3) and the second segment may include a DMRS symbol period 415 (e.g., at symbol period 10).

In some cases, a location of a starting symbol period (e.g., a first period of a mini-slot, a symbol period for AGC operations, a candidate starting symbol) may be configured (e.g., selected by a network entity 105, selected by a UE 115) to avoid DMRS symbol periods 415. In such cases, a UE 115 or a network entity 105 may coordinate (e.g., select, configure) the location of AGC symbol periods 310 based on the location of DMRS symbol periods 415 so that there is no overlap (e.g., AGC symbol periods 310 and DMRS symbol periods 415 do not occupy a same symbol period of a slot 405). Additionally, or alternatively, a UE 115 may coordinate (e.g., select, configure) the location of AGC symbol periods 310 based on the location of DMRS symbol periods 415 so that each AGC symbol period 310 precedes a DMRS symbol period 415. In some cases, a DMRS symbol period 415 included in a segment of PSSCH symbol periods 420 may be during a symbol that is not the first symbol of the segment. In some cases, a quantity of DMRS symbol periods 415 in a slot 405 may be greater than a quantity of AGC symbol periods 310 in a same slot 405.

In some cases, a pattern (e.g., a configuration, an ordering) for DMRS symbol periods 415 may be based on a pattern (e.g., a configuration, an ordering) for starting symbols for subslot-based communications (e.g., mini-slot starting symbols). For example, a same pattern may be utilized for DMRS symbol periods 415 and starting symbols for subslot-based communications. In some cases, a quantity of DMRS symbol periods 415 in a slot 405 may be greater than a quantity of starting symbols for subslot-based communications. In some cases, each segment of PSSCH symbol periods 420 may include at least one DMRS symbol period 415. Additionally, or alternatively, a location of a DMRS symbol period 415 may be selected (e.g., configured) to avoid a first symbol period of a segment of PSSCH symbol periods 420. Although the phrase “starting symbol” is described herein as referring to an initial symbol of a TTI for subslot based communications (e.g., a first symbol period of a mini-slot) the phrase “starting symbol” may also be used to refer to a symbol period for performing AGC operations (e.g., an AGC symbol period 310).

Table 1, as shown below, illustrates various configurations (e.g., patterns, mappings) for DMRS symbol periods 415 (e.g., within a TTI, such as a slot 405). For example, a location of one or more DMRS symbol periods 415 within a slot 405 may be based on a quantity of symbol periods in the slot (e.g., of any type), a quantity of PSCCH symbol periods 410 in the slot 405, and a quantity of DMRS symbol periods 415 in the slot 405. As an illustrative example, and as shown below in Table 1, a slot 405 having 13 symbol periods, two PSCCH symbol periods 410, and two DMRS symbol periods 415 may have DMRS symbol periods 415 at a third symbol period of the slot 405 and a tenth symbol period of the slot 405. In such an illustrative example, a first starting symbol may be located between a symbol period 0 and a symbol period 2 (e.g., prior to the DMRS symbol period 415 at the third symbol period). Additionally, or alternatively, a second starting symbol may be located between a symbol period 4 and a symbol period 9 (e.g., following the DMRS symbol period 415 at the third symbol period and prior to the DMRS symbol period 415 at the tenth symbol period).

TABLE 1

| | DMRS Position | | | | | |
|---|---|---|---|---|---|---|
| Quantity | 2 PSCCH Symbols | | | 3 PSCCH Symbols | | |
| of | 2 | 3 | 4 | 2 | 3 | 4 |
| Symbols | DMRSs | DMRSs | DMRSs | DMRSs | DMRSs | DMRSs |
| 6 | 1, 5 | | | 1, 5 | | |
| 7 | 1, 5 | | | 1, 5 | | |
| 8 | 1, 5 | | | 1, 5 | | |
| 9 | 3, 8 | 1, 4, 7 | | 4, 8 | 1, 4, 7 | |
| 10 | 3, 8 | 1, 4, 7 | | 4, 8 | 1, 4, 7 | |
| 11 | 3, 10 | 1, 5, 9 | 1, 4, 7, 10 | 4, 10 | 1, 5, 9 | 1, 4, 7, 10 |
| 12 | 3, 10 | 1, 5, 9 | 1, 4, 7, 10 | 4, 10 | 1, 5, 9 | 1, 4, 7, 10 |
| 13 | 3, 10 | 1, 6, 11 | 1, 4, 7, 10 | 4, 10 | 1, 6, 11 | 1, 4, 7, 10 |

In some cases, a network entity 105 may configure a quantity of AGC symbol periods 310 within a slot 405 for one or more UEs 115 (e.g., transmitting UEs 115 and receiving UEs 115). To reduce AGC overhead or to avoid PSSCH performance loss, a network entity 105 may want to turn on or turn off the transmission of multiple AGC symbol periods 310 (e.g., second AGC symbol periods 310 in a slot 405) and the second AGC adaptation at the receiver based on network conditions. That is, a network entity 105 may select whether multiple AGC symbol periods 310 are included in a slot 405. For example, a network entity 105 may configure (e.g., turn on, turn off) the transmission of one or more AGC symbol periods 310 (e.g., symbol period 7) for a UE 115. Additionally, or alternatively, a network entity 105 may configure (e.g., turn on, turn off) the reception of one or more AGC symbol periods 310 for a UE 115. For example, a network entity 105 may configure a UE 115 whether to perform a second AGC adaptation in a slot 405. The network entity 105 may configure whether the UE 115 is to perform a second AGC in a slot 405 based on one or more network conditions (e.g., a quantity of PC5 links configured with half-slot access). In some cases, a network entity 105 may configure the quantity of AGC symbol periods 310 within a slot 405 to reduce overhead or to avoid PSSCH performance loss (e.g., to increase a quantity of PSSCH symbol periods 410 in a slot 405).

As an illustrative example, a network entity 105 may configure a UE 115 (e.g., a transmitter) to transmit multiple AGC symbol periods 310 in a slot 405 when sending a transmission (e.g., in a PSCCH/PSSCH transmission, in a slot 405, in a slot 405). The network entity 105 may configure the UE 115 to transmit the multiple AGC symbol periods 310 if a quantity of PC5 links configured with half-slot access satisfies a threshold quantity. The network entity 105 may transmit an indication of the configuration to one or more UEs 115 semi-statically via layer 2 (L2) signaling, layer 3 (L3) signaling, or via a DCI grant, or a combination thereof. For example, a network entity 105 may transmit a MAC-CE, or RRC signaling to one or more UEs 115, which may include an indication of the configuration.

In some other cases, a UE 115 may transmit an indication of the configuration to another UE 115. For example, a UE 115 (e.g., a transmitter) may transmit control signaling (e.g., SCI-2 signaling, L2 signaling, L3 signaling, PC5 signaling) to a different UE 115 that indicates whether to perform one or more AGC operations (e.g., AGC adaptations). In some cases, a UE 115 may transmit a slot 405 with multiple AGC symbol periods 310 (e.g., in the middle of the slot 405). The UE 115 may also indicate to other UEs 115 (e.g., other UEs 115 that are scheduled to receive a transmission during the slot 405 with multiple AGC symbol periods 310) to perform multiple AGC operations corresponding to the quantity of AGC symbol periods 310 transmitted by the UE 115. In some cases, a UE 115 may transmit the indication of the configuration based on receiving the indication from a network entity 105. For example, the UE 115 may relay the configuration from the network entity 105 to other UEs 115. In such cases, a UE 115 may not transmit multiple AGC symbol periods 310 in a slot 405, but may still transmit the indication of the configuration regardless.

In some cases, a receiving UE 115 may determine (e.g., independently) whether to perform one or more AGC operations (e.g., whether to adjust an AGC setting in a 2nd or later starting symbol) based on a result of an energy detection operation, which may lead to more efficient utilization of communication resources. For example, a receiving UE 115 may perform one or more energy detection operations and may determine whether to perform AGC adjustment during a slot 405 based on performing the one or more energy detection operations (e.g., based on one or more results of the one or more energy detection operations). In such cases, a receiving UE 115 may determine to utilize one or more symbol periods for communications (e.g., for PSCCH symbol periods 410, for PSSCH symbol periods 420) if the receiving UE 115 does not detect a change in an energy level.

A UE 115 may perform wideband energy detection on a second starting symbol and may decide to perform AGC adjustment based on a comparison against previously estimated energy. If an estimated energy difference (e.g., between a starting symbol period and a symbol period prior to the starting symbol period) is below a preconfigured threshold, a UE 115 may decode a PSSCH symbol period 420 during the starting symbol (e.g., the UE 115 may refrain from performing AGC for the starting symbol). Additionally, or alternatively, the UE 115 may use one or more channel estimation parameters for a previous period (e.g., a preceding symbol period, a preceding PSSCH segment) for the starting symbol and subsequent symbol periods.

In some other cases, if the estimated energy difference satisfies a threshold (e.g., is greater than a threshold), a UE 115 may puncture one or more PSSCH symbol periods 420 (e.g., to perform an AGC operation during the punctured one or more PSSCH symbol periods 420). In such cases, the PSSCH symbol period 420 (e.g., the punctured PSSCH symbol period 420) may overlap with a starting symbol for subslot-based communications (e.g., a mini-slot starting symbol). Additionally, or alternatively, a UE 115 may apply a new gain state (e.g., based on performing the AGC operation) during the punctured PSSCH symbol period 420. A UE 115 may perform independent channel estimation for symbol periods subsequent to the punctured PSSCH symbol period 420 (e.g., for a 2nd PSSCH segment starting from the 2nd starting symbol). The above principal may apply if more than two starting symbols are configured.

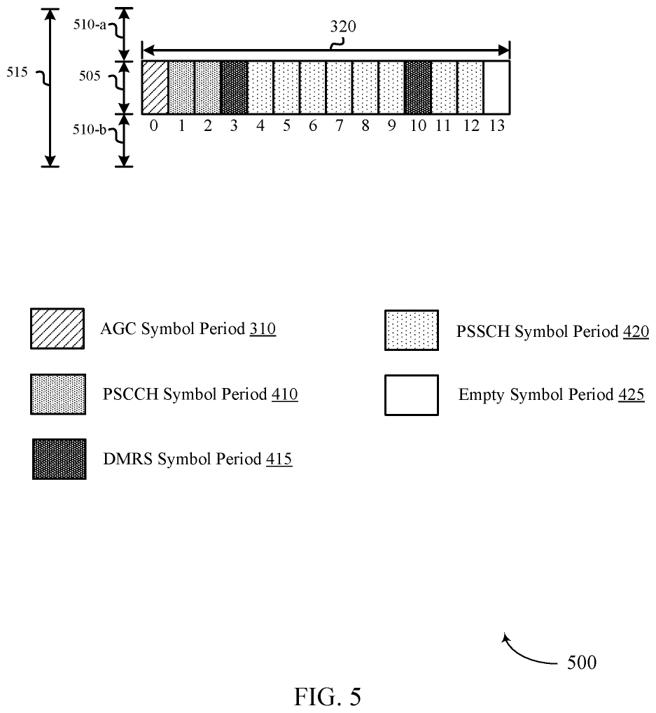

FIG. 5 illustrates an example of a resource configuration 500 that supports methods for automatic gain control in accordance with one or more aspects of the present disclosure. The resource configuration 500 may be implemented by one or more aspects of the wireless communication system 100, the network architecture 200, or the wireless communications system 300. For example, a network device, such as a UE 115 or a network entity 105 as described with reference to FIGS. 1-3, may communicate using one or more aspects of the resource configuration 500. The resource configuration 500 may include one or more AGC symbol periods 310, one or more PSCCH symbol periods 410, one or more DMRS symbol periods 415, one or more PSSCH symbol periods 420, and one or more empty symbol periods 425 (e.g., one or more gaps), which may be examples of one or more respective aspects of FIG. 4. Additionally, or alternatively, the resource configuration 500 may include a slot 320, a target RB set 505, one or more offsets 510, and a frequency range 515.

In some cases, a UE 115 (e.g., a UE 115 that transmits mini-slots) may backoff to full-slot transmissions in nearby RB sets if full slot transmissions are detected. For example, a UE 115 may refrain from transmitting mini-slots (e.g., in the middle of a slot 320) based on detecting slot-based communications. In such cases, a UE 115 (e.g., a receiving UE 115) may not perform multiple AGC adjustments within a slot 320. In some cases, a UE 115 (e.g., that transmits mini-slots) may monitor for slot-based transmissions (e.g., SCI-1 signaling, PSCCH signaling, DMRSs) in a frequency range 515 around a target RB set 505. The target RB set 505 may include one or more RBs for slot-based communications (e.g., communications in the slot 320). Additionally, or alternatively, a UE 115 may limit or cease transmissions in a slot 320 (e.g., mini-slot transmissions in the middle of a slot 320) based on a reference signal received power (RSRP) and priority for subslot-based communications, for slot-based communications, or both.

For example, if a UE 115 receives the slot 320 (e.g., an SCI transmission or a PSCCH DMRS) having an RSRP that satisfies a threshold RSRP and a priority that satisfies a threshold priority, the UE 115 may determine not to transmit subslot-based communications in the middle of the slot 320. Additionally, or alternatively, if a UE 115 does not receive the slot 320, the UE 115 may transmit subslot-based communications in the middle of the slot 320. Additionally, or alternatively, if a UE 115 receives the slot 320 and the slot 320 has an RSRP below a threshold RSRP, the UE 115 may transmit subslot-based communications (e.g., in the middle of the slot 320). In some other cases, if a UE 115 receives the slot 320 and the slot 320 has a priority below a threshold priority, the UE 115 may transmit subslot-based communications (e.g., in the middle of the slot 320).

In some cases, an offset 510 (e.g., an RB offset threshold, X) may be configured (e.g., by a network entity 105), and a UE 115 (e.g., a UE 115 that transmits mini-slots) may monitor for SCI-1 or PSCCH DMRS communications within a frequency range 515 around the target RB set 505 (e.g., a range defined by the target RB set 505 plus or minus the RB offset threshold, X). That is, the frequency range 515 may be based on (e.g., may include) the target RB set 505, the offset 510-a, and the offset 510-b. In some cases, a UE 115 (e.g., a UE 115 that receives slot-based communications) may be a narrow-band receiver that monitors one or more RB sets. In such cases, a UE 115 (e.g., a UE 115 that transmits subslot-based communications) may transmit using an RB set that is different from the one or more RB sets monitored by the narrow-band receiver (e.g., not included in the frequency range 515, not included in the target RB set 505), which may reduce or eliminate interference.

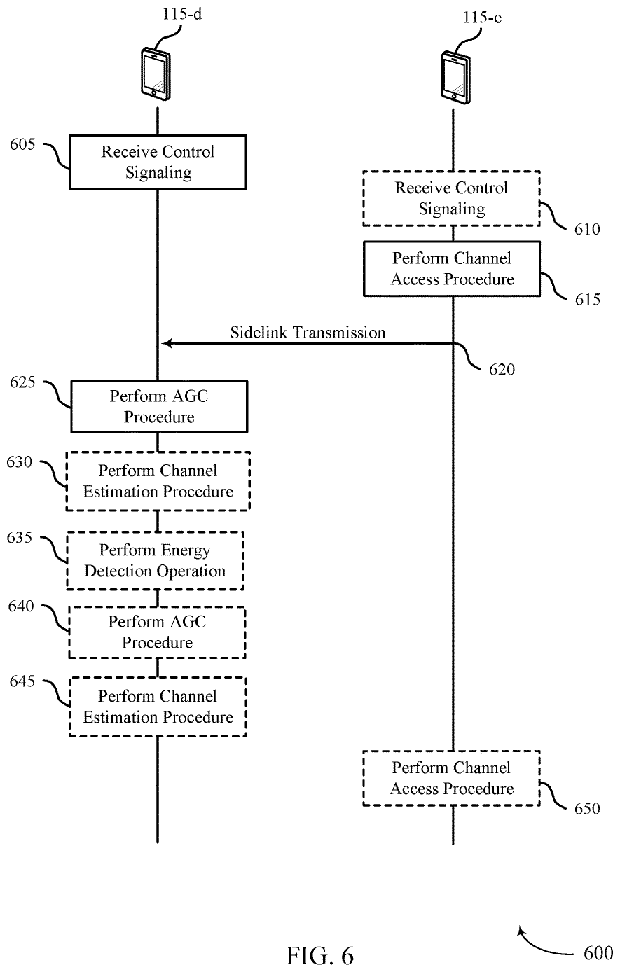

FIG. 6 illustrates an example of a process flow 600 that supports methods for automatic gain control in accordance with one or more aspects of the present disclosure. In some cases, the process flow 600 may implement aspects of the wireless communications system 100, the network architecture 200, the wireless communications system 300, or the resource configurations 400. For example, the process flow 600 may include a UE 115-d and a UE 115-e, which may be examples of corresponding UEs 115 as described with reference to FIGS. 1-3. In some cases, the UEs 115 may perform AGC operations, as described with reference to FIGS. 1-4, which may improve communications between the UEs 115.

In the following description of the process flow 600, the operations between the UE 115-d and the UE 115-e may be performed in a different order than the order shown. Some operations may also be left out of the process flow 600, or other operations may be added to the process flow 600. Further, although some operations or communications may be shown to occur at different times for discussion purposes, these operations may occur at the same time. Additionally, or alternatively, although the UE 115-d and the UE 115-e are shown performing a number of the operations of process flow 600, any wireless device may perform the operations shown.

At 605, the UE 115-d may identify, for example, by receiving control signaling (e.g., from a network entity 105, from the UE 115-e, from a UE 115 different from the UE 115-e) indicating, an AGC parameter that indicates to perform multiple AGC procedures during a slot of a sidelink channel, or the AGC parameter indicates to perform the multiple AGC procedures during the slot based on an energy detection result for a defined symbol period of the slot. The defined symbol period occurring after a beginning symbol period of the slot. In some cases, the slot includes multiple DMRS symbol periods and multiple AGC symbol periods, each AGC symbol period of the multiple AGC symbol periods configured based on a pattern for the multiple DMRS symbol periods. In some cases, the slot includes a first DMRS symbol period subsequent to a first AGC symbol period and a second DMRS symbol period subsequent to a second AGC symbol period. The slot may include a same quantity of DMRS symbol periods and AGC symbol periods.

In some cases, the UE 115-d may receive, from a network entity 105, the control signaling indicating the AGC parameter that indicates to perform a second AGC procedure, where the control signaling is based on whether a quantity of communication links established with the network entity are configured for communications using subslots. In some cases, the control signaling includes a MAC-CE, RRC signaling, or a DCI grant, the control signaling received semi-statically. In some cases, the UE 115-d may receive the control signal from a different UE 115 (e.g., the UE 115-e or any other UE 115). In such cases, the control signaling may indicate the AGC parameter that indicates to perform a second AGC procedure, where the control signaling is based on the different UE 115 transmitting an AGC signal on the defined symbol period of the slot. In some cases, the AGC parameter may indicate to perform a second AGC procedure based on an indication from a network entity 105 to perform the second AGC procedure.

At 610, the UE 115-e may receive control signaling indicating the threshold frequency offset for monitoring for the sidelink control information, the sidelink reference signal, or both, relative to a target sidelink frequency band. In some cases, the UE 115-e may receive the control signaling from a different UE 115. For example, the UE 115-e may receive the control signaling from the UE 115-d. In some other cases, the UE 115-e may receive the control signaling from a UE 115 different from the UE 115-d. In some other cases, the UE 115-e may receive the control signaling from a network entity 105.

At 615, the UE 115-e may perform a channel access procedure within frequency resources positioned relative to a first sidelink frequency band to monitor for sidelink control information, a sidelink reference signal, or both, to determine whether full slot transmission by a UE 115 (e.g., the UE 115-d, any other UE 115) is scheduled to occur within a first slot. In some cases, the frequency resources may occur within a threshold frequency offset of the first sidelink frequency band. In some cases, the frequency resources are adjacent to the first sidelink frequency band. Additionally, or alternatively, the channel access procedure may include monitoring for full slot transmissions.

At 620, the UE 115-d may receive, via a sidelink control channel, a sidelink transmission, which may be slot-based or sub-slot based. In some cases, a portion of the sidelink transmission may be received using the first gain state. In some cases, the sidelink transmission may include a sidelink grant indicating that a sidelink transmission is scheduled for the UE 115-d in a sidelink shared data channel of the slot (e.g., in a PSSCH of the slot). In some cases, the UE 115-d may adjust a gain state of one or more receiving components to the first gain state and may receive the sidelink grant using the first gain state. The sidelink grant may be transmitted by the UE 115-e or the sidelink grant may be transmitted by a network entity 105.

Additionally, or alternatively, the UE 115-d may receive, using the first gain state and a second gain state determined in accordance with the AGC parameter, the sidelink transmission (e.g., the message) via the sidelink shared data channel of the slot. Additionally, or alternatively, the sidelink transmission may be transmitted by the UE 115-e. The UE 115-e may transmit the sidelink transmission based on the sidelink grant. For example, the sidelink grant may schedule the sidelink transmission. Additionally, or alternatively, the sidelink transmission may include a quantity of symbol periods (e.g., one or more slots). Accordingly, the UE 115-d may receive a first portion of the sidelink transmission using the first gain state and a second portion of the sidelink transmission using the second gain state (e.g., after 640, after 645).

At 625, the UE 115-d may perform, based on the identifying, a first AGC procedure of multiple AGC procedures on the beginning symbol period of the slot that includes the sidelink to determine a first gain state for receiving a sidelink grant via a sidelink control channel of the slot. For example, the control signaling may indicate that the UE 115-d should perform multiple AGC procedures during a slot. Accordingly, the UE 115-d may perform at least the first AGC procedure based on the indication that the UE 115-d should perform the multiple AGC procedures during the slot. In some cases, the first gain state may be used for receiving one or more other transmissions. For example, the first gain state may be applied to multiple transmissions subsequent to the AGC procedure.

At 630, the UE 115-d may perform a first channel estimation procedure for the sidelink shared data channel during a second symbol period of the slot, the first channel estimation procedure using the first gain state. In some cases, the channel estimation procedure may enable the UE 115-d to evaluate a quality of a channel. Additionally, or alternatively, the channel estimation procedure may be based on the first gain state. For example, the UE 115-d may utilize the first gain state to receive communications during the channel estimation procedure. In some cases, the channel estimation procedure may determine a quality of a channel for subsequent communications (e.g., received using the first gain state).

At 635, the UE 115-d may perform an energy detection operation. For example, the UE 115-d may measure an energy detection result for a third symbol period of the slot, the defined symbol period of the slot subsequent to the third symbol period of the slot. Additionally, or alternatively, the UE 115-d may measure the energy detection result for the defined symbol period of the slot. The UE 115-d may also compare the energy detection result for the third symbol period to the energy detection result for the defined symbol period, where a second AGC procedure is performed on the defined symbol period of the slot based on the comparing. In some cases, the UE 115-d may puncture the defined symbol period based on a difference between an energy detection result for a third symbol period and the energy detection result for the defined symbol period exceeding a threshold difference. Additionally, or alternatively, the defined symbol period of the slot may overlap with a second beginning symbol period of a subslot of the slot.

At 640, the UE 115-d may perform a second AGC procedure. The UE 115-d may perform the second AGC procedure in a same slot as the first AGC procedure. Additionally, or alternatively, the UE 115-d may perform the second AGC procedure based on a configuration for performing multiple AGC procedures within a slot. The UE 115-d may receive an indication of the configuration from a network entity 105, from a different UE 115 (e.g., the UE 115-e), or both. Additionally, or alternatively, performing the second AGC procedure may enable the UE 115-d to adjust AGC settings during a slot, which may enable more effective reception of subslot-based communications (e.g., if mini-slots are received during a slot).

At 645, the UE 115-d may perform a second channel estimation procedure for the sidelink shared data channel during a third symbol period of the slot, the second channel estimation procedure using the second gain state. In some cases, the second channel estimation procedure may be performed subsequently to the first channel estimation procedure. In some cases, the second channel estimation procedure may enable the UE 115-d to evaluate a quality of a channel. Additionally, or alternatively, the second channel estimation procedure may be based on the second gain state. For example, the UE 115-d may utilize the second gain state to receive communications during the second channel estimation procedure. In some cases, the second channel estimation procedure may determine a quality of a channel for subsequent communications (e.g., received using the second gain state).

At 650, the UE 115-e may perform a second channel access procedure within frequency resources positioned relative to the first sidelink frequency band to monitor for the sidelink control information, the sidelink reference signal, or both. In some cases, the UE 115-e may detect full slot transmissions based on performing the channel access procedure. In such cases, the UE 115-e may refrain from transmitting one or more messages (e.g., second messages, mini-slots) via the first sidelink frequency band based on the second channel access procedure indicating that the frequency resources are unavailable (e.g., indicating that full slot transmissions are occurring).

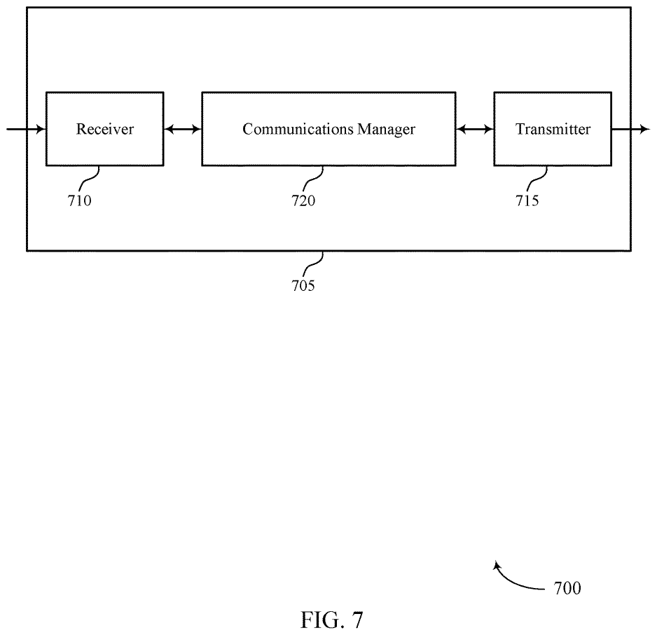

FIG. 7 illustrates a block diagram 700 of a device 705 that supports methods for automatic gain control in accordance with one or more aspects of the present disclosure. The device 705 may be an example of aspects of a UE 115 as described herein. The device 705 may include a receiver 710, a transmitter 715, and a communications manager 720. The device 705 may also include a processor. Each of these components may be in communication with one another (e.g., via one or more buses).

The receiver 710 may provide a means for receiving information such as packets, user data, control information, or any combination thereof associated with various information channels (e.g., control channels, data channels, information channels related to methods for automatic gain control). Information may be passed on to other components of the device 705. The receiver 710 may utilize a single antenna or a set of multiple antennas.

The transmitter 715 may provide a means for transmitting signals generated by other components of the device 705. For example, the transmitter 715 may transmit information such as packets, user data, control information, or any combination thereof associated with various information channels (e.g., control channels, data channels, information channels related to methods for automatic gain control). In some examples, the transmitter 715 may be co-located with a receiver 710 in a transceiver module. The transmitter 715 may utilize a single antenna or a set of multiple antennas.

The communications manager 720, the receiver 710, the transmitter 715, or various combinations thereof or various components thereof may be examples of means for performing various aspects of methods for automatic gain control as described herein. For example, the communications manager 720, the receiver 710, the transmitter 715, or various combinations or components thereof may support a method for performing one or more of the functions described herein.

In some examples, the communications manager 720, the receiver 710, the transmitter 715, or various combinations or components thereof may be implemented in hardware (e.g., in communications management circuitry). The hardware may include a processor, a digital signal processor (DSP), a central processing unit (CPU), an application-specific integrated circuit (ASIC), a field-programmable gate array (FPGA) or other programmable logic device, a microcontroller, discrete gate or transistor logic, discrete hardware components, or any combination thereof configured as or otherwise supporting a means for performing the functions described in the present disclosure. In some examples, one or more processors and one or more memories coupled with the one or more processors may be configured to perform one or more of the functions described herein (e.g., by executing, by the one or more processors, instructions stored in the one or more memories).

Additionally, or alternatively, in some examples, the communications manager 720, the receiver 710, the transmitter 715, or various combinations or components thereof may be implemented in code (e.g., as communications management software or firmware) executed by a processor. If implemented in code executed by a processor, the functions of the communications manager 720, the receiver 710, the transmitter 715, or various combinations or components thereof may be performed by a general-purpose processor, a DSP, a CPU, an ASIC, an FPGA, a microcontroller, or any combination of these or other programmable logic devices (e.g., configured as or otherwise supporting a means for performing the functions described in the present disclosure).

In some examples, the communications manager 720 may be configured to perform various operations (e.g., receiving, obtaining, monitoring, outputting, transmitting) using or otherwise in cooperation with the receiver 710, the transmitter 715, or both. For example, the communications manager 720 may receive information from the receiver 710, send information to the transmitter 715, or be integrated in combination with the receiver 710, the transmitter 715, or both to obtain information, output information, or perform various other operations as described herein.

The communications manager 720 may support wireless communications at a first UE in accordance with examples as disclosed herein. For example, the communications manager 720 may be configured as or otherwise support a means for identifying an automatic gain control parameter that indicates to perform multiple automatic gain control procedures during a slot of a sidelink channel, or the automatic gain control parameter indicates to perform the multiple automatic gain control procedures during the slot based on an energy detection result for a defined symbol period of the slot, the defined symbol period occurring after a beginning symbol period of the slot. The communications manager 720 may be configured as or otherwise support a means for performing, based on the identifying, a first automatic gain control procedure of the multiple automatic gain control procedures on the beginning symbol period of the slot to determine a first gain state for receiving a sidelink grant via a sidelink control channel of the slot. The communications manager 720 may be configured as or otherwise support a means for receiving, via the sidelink control channel in accordance with the first gain state, the sidelink grant indicating that a sidelink transmission is scheduled for the first UE in a sidelink shared data channel of the slot. The communications manager 720 may be configured as or otherwise support a means for receiving, using the first gain state and a second gain state determined in accordance with the automatic gain control parameter, the sidelink transmission via the sidelink shared data channel of the slot.

Additionally, or alternatively, the communications manager 720 may support wireless communications in accordance with examples as disclosed herein. For example, the communications manager 720 may be configured as or otherwise support a means for performing a channel access procedure within frequency resources positioned relative to a first sidelink frequency band to monitor for sidelink control information, a sidelink reference signal, or both, to determine whether full slot transmission by a second UE is scheduled to occur within a first slot, the frequency resources occurring within a threshold frequency offset of the first sidelink frequency band. The communications manager 720 may be configured as or otherwise support a means for transmitting a sidelink grant indicating that one or more messages are scheduled for transmission via the first sidelink frequency band in a subslot of the first slot. The communications manager 720 may be configured as or otherwise support a means for transmitting, in the subslot, the one or more messages via the first sidelink frequency band based on the channel access procedure indicating that the frequency resources are available during the first slot.

By including or configuring the communications manager 720 in accordance with examples as described herein, the device 705 (e.g., a processor controlling or otherwise coupled with the receiver 710, the transmitter 715, the communications manager 720, or a combination thereof) may support techniques for performing multiple AGC procedures within a slot, which may reduce power consumption. For example, performing multiple AGC procedures within a slot may enable the device 605 to reduce a gain for receiving communications during a slot, which may reduce power consumption (e.g., for a portion of the slot where gain is reduced). Additionally, or alternatively, the device 605 may support configurations for determining whether to perform multiple AGC operations during a slot (e.g., based on control signaling), which may reduce power consumption and improve utilization of communication resources. For example, if the device 605 determines to refrain from performing multiple AGC operations within a slot, one or more symbol periods may be utilized for communications instead of performing the AGC operations.

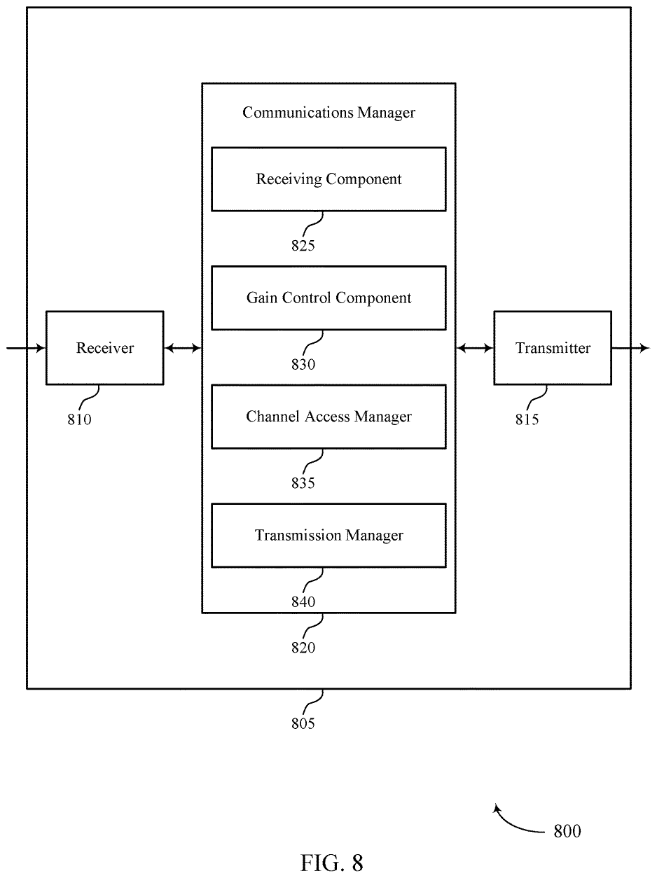

FIG. 8 illustrates a block diagram 800 of a device 805 that supports methods for automatic gain control in accordance with one or more aspects of the present disclosure. The device 805 may be an example of aspects of a device 705 or a UE 115 as described herein. The device 805 may include a receiver 810, a transmitter 815, and a communications manager 820. The device 805 may also include a processor. Each of these components may be in communication with one another (e.g., via one or more buses).

The receiver 810 may provide a means for receiving information such as packets, user data, control information, or any combination thereof associated with various information channels (e.g., control channels, data channels, information channels related to methods for automatic gain control). Information may be passed on to other components of the device 805. The receiver 810 may utilize a single antenna or a set of multiple antennas.

The transmitter 815 may provide a means for transmitting signals generated by other components of the device 805. For example, the transmitter 815 may transmit information such as packets, user data, control information, or any combination thereof associated with various information channels (e.g., control channels, data channels, information channels related to methods for automatic gain control). In some examples, the transmitter 815 may be co-located with a receiver 810 in a transceiver module. The transmitter 815 may utilize a single antenna or a set of multiple antennas.

The device 805, or various components thereof, may be an example of means for performing various aspects of methods for automatic gain control as described herein. For example, the communications manager 820 may include a receiving component 825, a gain control component 830, a channel access manager 835, a transmission manager 840, or any combination thereof. The communications manager 820 may be an example of aspects of a communications manager 720 as described herein. In some examples, the communications manager 820, or various components thereof, may be configured to perform various operations (e.g., receiving, obtaining, monitoring, outputting, transmitting) using or otherwise in cooperation with the receiver 810, the transmitter 815, or both. For example, the communications manager 820 may receive information from the receiver 810, send information to the transmitter 815, or be integrated in combination with the receiver 810, the transmitter 815, or both to obtain information, output information, or perform various other operations as described herein.

The communications manager 820 may support wireless communications at a first UE in accordance with examples as disclosed herein. The receiving component 825 may be configured as or otherwise support a means for identifying an automatic gain control parameter that indicates to perform multiple automatic gain control procedures during a slot of a sidelink channel, or the automatic gain control parameter indicates to perform the multiple automatic gain control procedures during the slot based on an energy detection result for a defined symbol period of the slot, the defined symbol period occurring after a beginning symbol period of the slot. The gain control component 830 may be configured as or otherwise support a means for performing, based on the identifying, a first automatic gain control procedure of the multiple automatic gain control procedures on the beginning symbol period of the slot to determine a first gain state for receiving a sidelink grant via a sidelink control channel of the slot. The receiving component 825 may be configured as or otherwise support a means for receiving, via the sidelink control channel in accordance with the first gain state, the sidelink grant indicating that a sidelink transmission is scheduled for the first UE in a sidelink shared data channel of the slot. The receiving component 825 may be configured as or otherwise support a means for receiving, using the first gain state and a second gain state determined in accordance with the automatic gain control parameter, the sidelink transmission via the sidelink shared data channel of the slot.

Additionally, or alternatively, the communications manager 820 may support wireless communications in accordance with examples as disclosed herein. The channel access manager 835 may be configured as or otherwise support a means for performing a channel access procedure within frequency resources positioned relative to a first sidelink frequency band to monitor for sidelink control information, a sidelink reference signal, or both, to determine whether full slot transmission by a second UE is scheduled to occur within a first slot, the frequency resources occurring within a threshold frequency offset of the first sidelink frequency band. The transmission manager 840 may be configured as or otherwise support a means for transmitting a sidelink grant indicating that one or more messages are scheduled for transmission via the first sidelink frequency band in a subslot of the first slot. The transmission manager 840 may be configured as or otherwise support a means for transmitting, in the subslot, the one or more messages via the first sidelink frequency band based on the channel access procedure indicating that the frequency resources are available during the first slot.

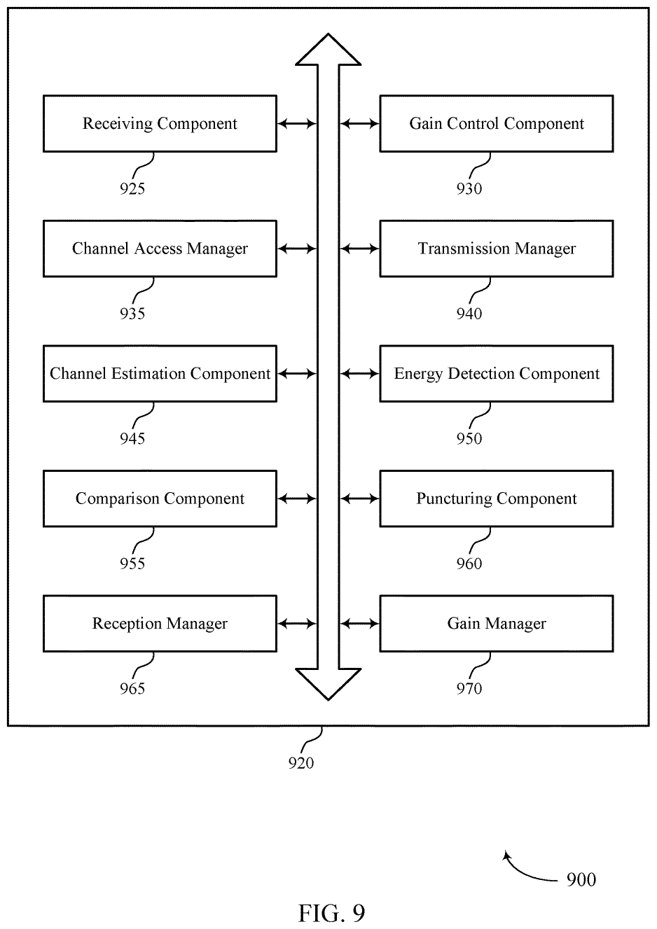

FIG. 9 illustrates a block diagram 900 of a communications manager 920 that supports methods for automatic gain control in accordance with one or more aspects of the present disclosure. The communications manager 920 may be an example of aspects of a communications manager 720, a communications manager 820, or both, as described herein. The communications manager 920, or various components thereof, may be an example of means for performing various aspects of methods for automatic gain control as described herein. For example, the communications manager 920 may include a receiving component 925, a gain control component 930, a channel access manager 935, a transmission manager 940, a channel estimation component 945, an energy detection component 950, a comparison component 955, a puncturing component 960, a reception manager 965, a gain manager 970, or any combination thereof. Each of these components may communicate, directly or indirectly, with one another (e.g., via one or more buses).

The communications manager 920 may support wireless communications at a first UE in accordance with examples as disclosed herein. The receiving component 925 may be configured as or otherwise support a means for identifying an automatic gain control parameter that indicates to perform multiple automatic gain control procedures during a slot of a sidelink channel, or the automatic gain control parameter indicates to perform the multiple automatic gain control procedures during the slot based on an energy detection result for a defined symbol period of the slot, the defined symbol period occurring after a beginning symbol period of the slot. The gain control component 930 may be configured as or otherwise support a means for performing, based on the identifying, a first automatic gain control procedure of the multiple automatic gain control procedures on the beginning symbol period of the slot to determine a first gain state for receiving a sidelink grant via a sidelink control channel of the slot. In some examples, the receiving component 925 may be configured as or otherwise support a means for receiving, via the sidelink control channel in accordance with the first gain state, the sidelink grant indicating that a sidelink transmission is scheduled for the first UE in a sidelink shared data channel of the slot. In some examples, the receiving component 925 may be configured as or otherwise support a means for receiving, using the first gain state and a second gain state determined in accordance with the automatic gain control parameter, the sidelink transmission via the sidelink shared data channel of the slot.

In some examples, the channel estimation component 945 may be configured as or otherwise support a means for performing a first channel estimation procedure for the sidelink shared data channel during a second symbol period of the slot, the first channel estimation procedure using the first gain state. In some examples, the channel estimation component 945 may be configured as or otherwise support a means for performing a second channel estimation procedure for the sidelink shared data channel during a third symbol period of the slot, the second channel estimation procedure using the second gain state.

In some examples, the receiving component 925 may be configured as or otherwise support a means for receiving a first demodulation reference signal during a second symbol period of the slot, the second symbol period subsequent to the beginning symbol period of the slot. In some examples, the receiving component 925 may be configured as or otherwise support a means for receiving a second demodulation reference signal during a third symbol period of the slot, the third symbol period of the slot subsequent to the defined symbol period of the slot.

In some examples, the slot includes a set of multiple demodulation reference signal symbol periods and a set of multiple automatic gain control symbol periods, each automatic gain control symbol period of the set of multiple automatic gain control symbol periods configured based on a pattern for the set of multiple demodulation reference signal symbol periods.

In some examples, the slot includes a first demodulation reference signal symbol period subsequent to a first automatic gain control symbol period and a second demodulation reference signal symbol period subsequent to a second automatic gain control symbol period.

In some examples, the slot includes a same quantity of demodulation reference signal symbol periods and automatic gain control symbol periods.

In some examples, the receiving component 925 may be configured as or otherwise support a means for receiving, from a network entity, control signaling indicating the automatic gain control parameter that indicates to perform a second automatic gain control procedure, where the control signaling is based on whether a quantity of communication links established with the network entity are configured for communications using subslots.

In some examples, the control signaling includes a medium access control control element, radio resource control signaling, or a downlink control information grant, the control signaling received semi-statically.

In some examples, the receiving component 925 may be configured as or otherwise support a means for receiving, from a second UE, control signaling indicating the automatic gain control parameter that indicates to perform a second automatic gain control procedure, where the control signaling is based on the second UE transmitting an automatic gain control signal on the defined symbol period of the slot.

In some examples, the receiving component 925 may be configured as or otherwise support a means for receiving, from a second UE, control signaling indicating the automatic gain control parameter that indicates to perform a second automatic gain control procedure based on an indication from a network entity to perform the second automatic gain control procedure.

In some examples, the energy detection component 950 may be configured as or otherwise support a means for measuring an energy detection result for a third symbol period of the slot, the defined symbol period of the slot subsequent to the third symbol period of the slot. In some examples, the energy detection component 950 may be configured as or otherwise support a means for measuring the energy detection result for the defined symbol period of the slot. In some examples, the comparison component 955 may be configured as or otherwise support a means for comparing the energy detection result for the third symbol period to the energy detection result for the defined symbol period, where a second automatic gain control procedure is performed on the defined symbol period of the slot based on the comparing.

In some examples, the puncturing component 960 may be configured as or otherwise support a means for puncturing the defined symbol period based on a difference between an energy detection result for a third symbol period and the energy detection result for the defined symbol period exceeding a threshold difference.

In some examples, the defined symbol period of the slot overlaps with a second beginning symbol period of a subslot of the slot.

Additionally, or alternatively, the communications manager 920 may support wireless communications in accordance with examples as disclosed herein. The channel access manager 935 may be configured as or otherwise support a means for performing a channel access procedure within frequency resources positioned relative to a first sidelink frequency band to monitor for sidelink control information, a sidelink reference signal, or both, to determine whether full slot transmission by a second UE is scheduled to occur within a first slot, the frequency resources occurring within a threshold frequency offset of the first sidelink frequency band. The transmission manager 940 may be configured as or otherwise support a means for transmitting a sidelink grant indicating that one or more messages are scheduled for transmission via the first sidelink frequency band in a subslot of the first slot. In some examples, the transmission manager 940 may be configured as or otherwise support a means for transmitting, in the subslot, the one or more messages via the first sidelink frequency band based on the channel access procedure indicating that the frequency resources are available during the first slot.

In some examples, the reception manager 965 may be configured as or otherwise support a means for receiving control signaling indicating the threshold frequency offset for monitoring for the sidelink control information, the sidelink reference signal, or both, relative to a target sidelink frequency band.

In some examples, to support receiving the control signaling, the reception manager 965 may be configured as or otherwise support a means for receiving the control signaling from the second UE.

In some examples, the channel access manager 935 may be configured as or otherwise support a means for performing a second channel access procedure within frequency resources positioned relative to the first sidelink frequency band to monitor for the sidelink control information, the sidelink reference signal, or both. In some examples, the transmission manager 940 may be configured as or otherwise support a means for refraining from transmitting one or more second messages via the first sidelink frequency band based on the second channel access procedure indicating that the frequency resources are unavailable.

In some examples, the gain manager 970 may be configured as or otherwise support a means for reducing a gain for one or more transmitting components of the first UE based on a reference signal receive power and a priority for the sidelink control information, the sidelink reference signal, or both.

In some examples, the frequency resources are adjacent to the first sidelink frequency band.

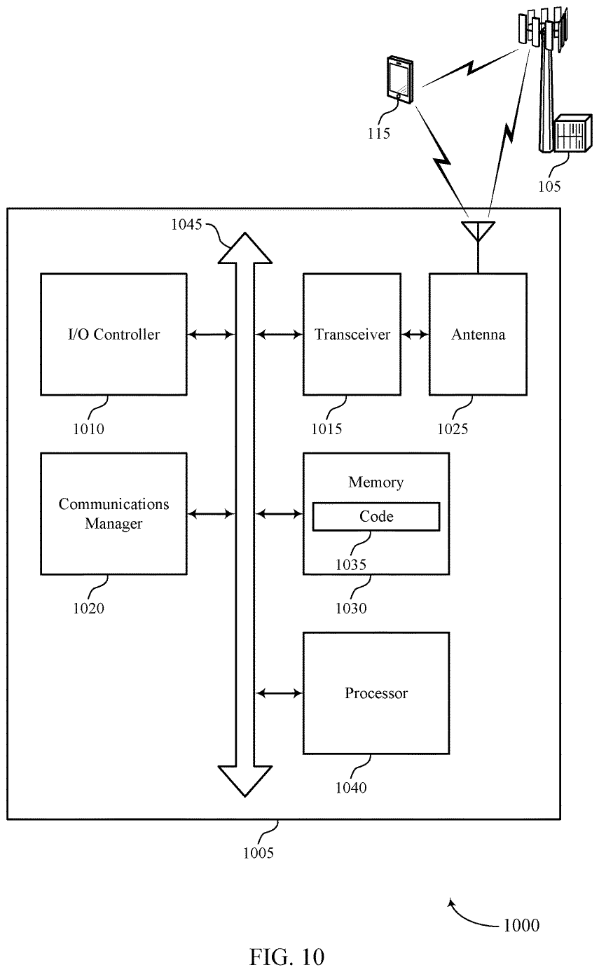

FIG. 10 illustrates a diagram of a system 1000 including a device 1005 that supports methods for automatic gain control in accordance with one or more aspects of the present disclosure. The device 1005 may be an example of or include the components of a device 705, a device 805, or a UE 115 as described herein. The device 1005 may communicate (e.g., wirelessly) with one or more network entities 105, one or more UEs 115, or any combination thereof. The device 1005 may include components for bi-directional voice and data communications including components for transmitting and receiving communications, such as a communications manager 1020, an input/output (I/O) controller 1010, a transceiver 1015, an antenna 1025, a memory 1030, code 1035, and a processor 1040. These components may be in electronic communication or otherwise coupled (e.g., operatively, communicatively, functionally, electronically, electrically) via one or more buses (e.g., a bus 1045).

The I/O controller 1010 may manage input and output signals for the device 1005. The I/O controller 1010 may also manage peripherals not integrated into the device 1005. In some cases, the I/O controller 1010 may represent a physical connection or port to an external peripheral. In some cases, the I/O controller 1010 may utilize an operating system such as iOS®, ANDROID®, MS-DOS®, MS-WINDOWS®, OS/2®, UNIX®, LINUX®, or another known operating system. Additionally or alternatively, the I/O controller 1010 may represent or interact with a modem, a keyboard, a mouse, a touchscreen, or a similar device. In some cases, the I/O controller 1010 may be implemented as part of a processor, such as the processor 1040. In some cases, a user may interact with the device 1005 via the I/O controller 1010 or via hardware components controlled by the I/O controller 1010.

In some cases, the device 1005 may include a single antenna 1025. However, in some other cases, the device 1005 may have more than one antenna 1025, which may be capable of concurrently transmitting or receiving multiple wireless transmissions. The transceiver 1015 may communicate bi-directionally, via the one or more antennas 1025, wired, or wireless links as described herein. For example, the transceiver 1015 may represent a wireless transceiver and may communicate bi-directionally with another wireless transceiver. The transceiver 1015 may also include a modem to modulate the packets, to provide the modulated packets to one or more antennas 1025 for transmission, and to demodulate packets received from the one or more antennas 1025. The transceiver 1015, or the transceiver 1015 and one or more antennas 1025, may be an example of a transmitter 715, a transmitter 815, a receiver 710, a receiver 810, or any combination thereof or component thereof, as described herein.

The memory 1030 may include random access memory (RAM) and read-only memory (ROM). The memory 1030 may store computer-readable, computer-executable code 1035 including instructions that, when executed by the processor 1040, cause the device 1005 to perform various functions described herein. The code 1035 may be stored in a non-transitory computer-readable medium such as system memory or another type of memory. In some cases, the code 1035 may not be directly executable by the processor 1040 but may cause a computer (e.g., when compiled and executed) to perform functions described herein. In some cases, the memory 1030 may contain, among other things, a basic I/O system (BIOS) which may control basic hardware or software operation such as the interaction with peripheral components or devices.

The processor 1040 may include an intelligent hardware device (e.g., a general-purpose processor, a DSP, a CPU, a microcontroller, an ASIC, an FPGA, a programmable logic device, a discrete gate or transistor logic component, a discrete hardware component, or any combination thereof). In some cases, the processor 1040 may be configured to operate a memory array using a memory controller. In some other cases, a memory controller may be integrated into the processor 1040. The processor 1040 may be configured to execute computer-readable instructions stored in a memory (e.g., the memory 1030) to cause the device 1005 to perform various functions (e.g., functions or tasks supporting methods for automatic gain control). For example, the device 1005 or a component of the device 1005 may include a processor 1040 and memory 1030 coupled with or to the processor 1040, the processor 1040 and memory 1030 configured to perform various functions described herein.

The communications manager 1020 may support wireless communications at a first UE in accordance with examples as disclosed herein. For example, the communications manager 1020 may be configured as or otherwise support a means for identifying an automatic gain control parameter that indicates to perform multiple automatic gain control procedures during a slot of a sidelink channel, or the automatic gain control parameter indicates to perform the multiple automatic gain control procedures during the slot based on an energy detection result for a defined symbol period of the slot, the defined symbol period occurring after a beginning symbol period of the slot. The communications manager 1020 may be configured as or otherwise support a means for performing, based on the identifying, a first automatic gain control procedure of the multiple automatic gain control procedures on the beginning symbol period of the slot to determine a first gain state for receiving a sidelink grant via a sidelink control channel of the slot. The communications manager 1020 may be configured as or otherwise support a means for receiving, via the sidelink control channel in accordance with the first gain state, the sidelink grant indicating that a sidelink transmission is scheduled for the first UE in a sidelink shared data channel of the slot. The communications manager 1020 may be configured as or otherwise support a means for receiving, using the first gain state and a second gain state determined in accordance with the automatic gain control parameter, the sidelink transmission via the sidelink shared data channel of the slot.

Additionally, or alternatively, the communications manager 1020 may support wireless communications in accordance with examples as disclosed herein. For example, the communications manager 1020 may be configured as or otherwise support a means for performing a channel access procedure within frequency resources positioned relative to a first sidelink frequency band to monitor for sidelink control information, a sidelink reference signal, or both, to determine whether full slot transmission by a second UE is scheduled to occur within a first slot, the frequency resources occurring within a threshold frequency offset of the first sidelink frequency band. The communications manager 1020 may be configured as or otherwise support a means for transmitting a sidelink grant indicating that one or more messages are scheduled for transmission via the first sidelink frequency band in a subslot of the first slot. The communications manager 1020 may be configured as or otherwise support a means for transmitting, in the subslot, the one or more messages via the first sidelink frequency band based on the channel access procedure indicating that the frequency resources are available during the first slot.

By including or configuring the communications manager 1020 in accordance with examples as described herein, the device 1005 may support techniques for performing AGC procedures multiple times within a slot, which may improve communication reliability. For example, the device 905 may adjust one or more gain parameters during a slot to more effectively receive communications if RSRP changes during the slot.

In some examples, the communications manager 1020 may be configured to perform various operations (e.g., receiving, monitoring, transmitting) using or otherwise in cooperation with the transceiver 1015, the one or more antennas 1025, or any combination thereof. Although the communications manager 1020 is illustrated as a separate component, in some examples, one or more functions described with reference to the communications manager 1020 may be supported by or performed by the processor 1040, the memory 1030, the code 1035, or any combination thereof. For example, the code 1035 may include instructions executable by the processor 1040 to cause the device 1005 to perform various aspects of methods for automatic gain control as described herein, or the processor 1040 and the memory 1030 may be otherwise configured to perform or support such operations.

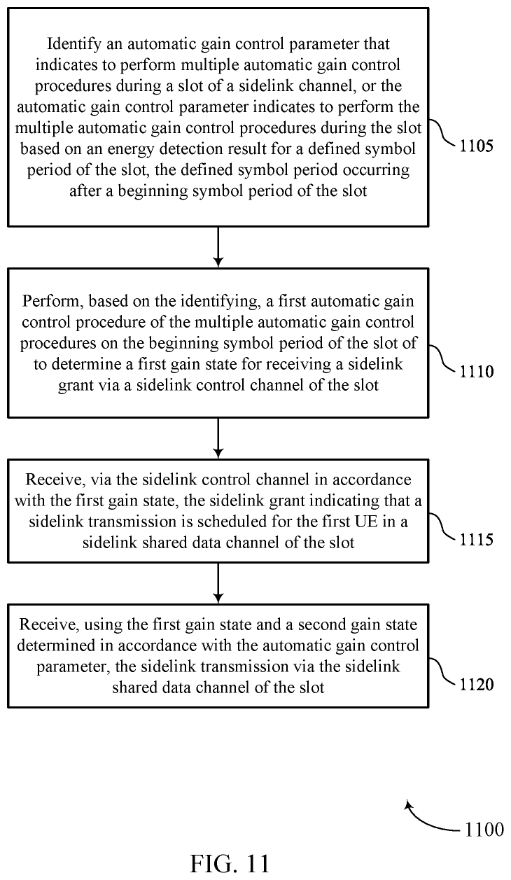

FIG. 11 illustrates a flowchart showing a method 1100 that supports methods for automatic gain control in accordance with one or more aspects of the present disclosure. The operations of the method 1100 may be implemented by a UE or its components as described herein. For example, the operations of the method 1100 may be performed by a UE 115 as described with reference to FIGS. 1 through 10. In some examples, a UE may execute a set of instructions to control the functional elements of the UE to perform the described functions. Additionally, or alternatively, the UE may perform aspects of the described functions using special-purpose hardware.

At 1105, the method may include identifying an automatic gain control parameter that indicates to perform multiple automatic gain control procedures during a slot of a sidelink channel, or the automatic gain control parameter indicates to perform the multiple automatic gain control procedures during the slot based on an energy detection result for a defined symbol period of the slot, the defined symbol period occurring after a beginning symbol period of the slot. The operations of 1105 may be performed in accordance with examples as disclosed herein. In some examples, aspects of the operations of 1105 may be performed by a receiving component 925 as described with reference to FIG. 9.

At 1110, the method may include performing, based on the identifying, a first automatic gain control procedure of the multiple automatic gain control procedures on the beginning symbol period of the slot to determine a first gain state for receiving a sidelink grant via a sidelink control channel of the slot. The operations of 1110 may be performed in accordance with examples as disclosed herein. In some examples, aspects of the operations of 1110 may be performed by a gain control component 930 as described with reference to FIG. 9.

At 1115, the method may include receiving, via the sidelink control channel in accordance with the first gain state, the sidelink grant indicating that a sidelink transmission is scheduled for the first UE in a sidelink shared data channel of the slot. The operations of 1115 may be performed in accordance with examples as disclosed herein. In some examples, aspects of the operations of 1115 may be performed by a receiving component 925 as described with reference to FIG. 9.

At 1120, the method may include receiving, using the first gain state and a second gain state determined in accordance with the automatic gain control parameter, the sidelink transmission via the sidelink shared data channel of the slot. The operations of 1120 may be performed in accordance with examples as disclosed herein. In some examples, aspects of the operations of 1120 may be performed by a receiving component 925 as described with reference to FIG. 9.

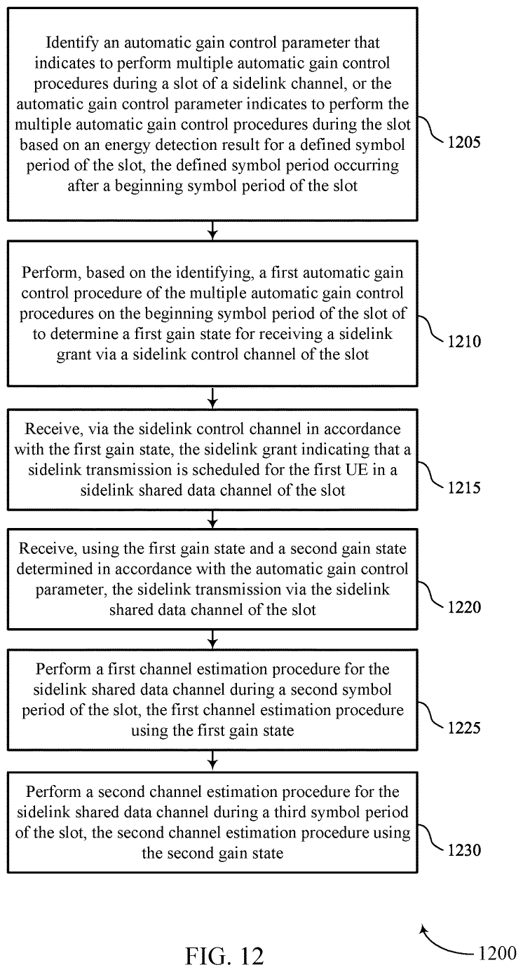

FIG. 12 illustrates a flowchart showing a method 1200 that supports methods for automatic gain control in accordance with one or more aspects of the present disclosure. The operations of the method 1200 may be implemented by a UE or its components as described herein. For example, the operations of the method 1200 may be performed by a UE 115 as described with reference to FIGS. 1 through 10. In some examples, a UE may execute a set of instructions to control the functional elements of the UE to perform the described functions. Additionally, or alternatively, the UE may perform aspects of the described functions using special-purpose hardware.

At 1205, the method may include identifying an automatic gain control parameter that indicates to perform multiple automatic gain control procedures during a slot of a sidelink channel, or the automatic gain control parameter indicates to perform the multiple automatic gain control procedures during the slot based on an energy detection result for a defined symbol period of the slot, the defined symbol period occurring after a beginning symbol period of the slot. The operations of 1205 may be performed in accordance with examples as disclosed herein. In some examples, aspects of the operations of 1205 may be performed by a receiving component 925 as described with reference to FIG. 9.

At 1210, the method may include performing, based on the identifying, a first automatic gain control procedure of the multiple automatic gain control procedures on the beginning symbol period of the slot to determine a first gain state for receiving a sidelink grant via a sidelink control channel of the slot. The operations of 1210 may be performed in accordance with examples as disclosed herein. In some examples, aspects of the operations of 1210 may be performed by a gain control component 930 as described with reference to FIG. 9.

At 1215, the method may include receiving, via the sidelink control channel in accordance with the first gain state, the sidelink grant indicating that a sidelink transmission is scheduled for the first UE in a sidelink shared data channel of the slot. The operations of 1215 may be performed in accordance with examples as disclosed herein. In some examples, aspects of the operations of 1215 may be performed by a receiving component 925 as described with reference to FIG. 9.

At 1220, the method may include receiving, using the first gain state and a second gain state determined in accordance with the automatic gain control parameter, the sidelink transmission via the sidelink shared data channel of the slot. The operations of 1220 may be performed in accordance with examples as disclosed herein. In some examples, aspects of the operations of 1220 may be performed by a receiving component 925 as described with reference to FIG. 9.

At 1225, the method may include performing a first channel estimation procedure for the sidelink shared data channel during a second symbol period of the slot, the first channel estimation procedure using the first gain state. The operations of 1225 may be performed in accordance with examples as disclosed herein. In some examples, aspects of the operations of 1225 may be performed by a channel estimation component 945 as described with reference to FIG. 9.

At 1230, the method may include performing a second channel estimation procedure for the sidelink shared data channel during a third symbol period of the slot, the second channel estimation procedure using the second gain state. The operations of 1230 may be performed in accordance with examples as disclosed herein. In some examples, aspects of the operations of 1230 may be performed by a channel estimation component 945 as described with reference to FIG. 9.

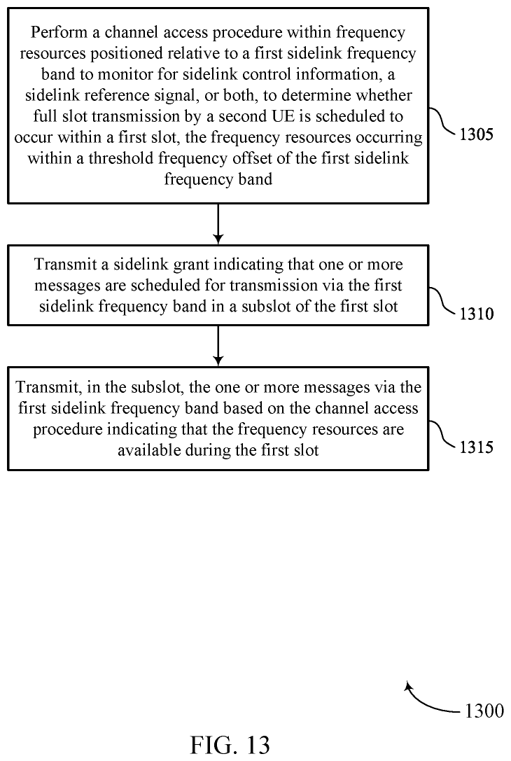

FIG. 13 illustrates a flowchart showing a method 1300 that supports methods for automatic gain control in accordance with one or more aspects of the present disclosure. The operations of the method 1300 may be implemented by a UE or its components as described herein. For example, the operations of the method 1300 may be performed by a UE 115 as described with reference to FIGS. 1 through 10. In some examples, a UE may execute a set of instructions to control the functional elements of the UE to perform the described functions. Additionally, or alternatively, the UE may perform aspects of the described functions using special-purpose hardware.

At 1305, the method may include performing a channel access procedure within frequency resources positioned relative to a first sidelink frequency band to monitor for sidelink control information, a sidelink reference signal, or both, to determine whether full slot transmission by a second UE is scheduled to occur within a first slot, the frequency resources occurring within a threshold frequency offset of the first sidelink frequency band. The operations of 1305 may be performed in accordance with examples as disclosed herein. In some examples, aspects of the operations of 1305 may be performed by a channel access manager 935 as described with reference to FIG. 9.

At 1310, the method may include transmitting a sidelink grant indicating that one or more messages are scheduled for transmission via the first sidelink frequency band in a subslot of the first slot. The operations of 1310 may be performed in accordance with examples as disclosed herein. In some examples, aspects of the operations of 1310 may be performed by a transmission manager 940 as described with reference to FIG. 9.

At 1315, the method may include transmitting, in the subslot, the one or more messages via the first sidelink frequency band based on the channel access procedure indicating that the frequency resources are available during the first slot. The operations of 1315 may be performed in accordance with examples as disclosed herein. In some examples, aspects of the operations of 1315 may be performed by a transmission manager 940 as described with reference to FIG. 9.

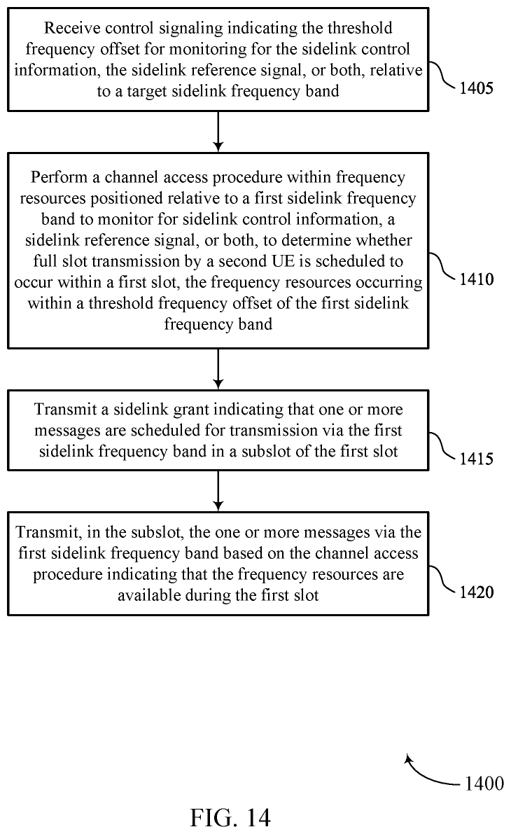

FIG. 14 illustrates a flowchart showing a method 1400 that supports methods for automatic gain control in accordance with one or more aspects of the present disclosure. The operations of the method 1400 may be implemented by a UE or its components as described herein. For example, the operations of the method 1400 may be performed by a UE 115 as described with reference to FIGS. 1 through 10. In some examples, a UE may execute a set of instructions to control the functional elements of the UE to perform the described functions. Additionally, or alternatively, the UE may perform aspects of the described functions using special-purpose hardware.

At 1405, the method may include receiving control signaling indicating the threshold frequency offset for monitoring for the sidelink control information, the sidelink reference signal, or both, relative to a target sidelink frequency band. The operations of 1405 may be performed in accordance with examples as disclosed herein. In some examples, aspects of the operations of 1405 may be performed by a reception manager 965 as described with reference to FIG. 9.

At 1410, the method may include performing a channel access procedure within frequency resources positioned relative to a first sidelink frequency band to monitor for sidelink control information, a sidelink reference signal, or both, to determine whether full slot transmission by a second UE is scheduled to occur within a first slot, the frequency resources occurring within a threshold frequency offset of the first sidelink frequency band. The operations of 1410 may be performed in accordance with examples as disclosed herein. In some examples, aspects of the operations of 1410 may be performed by a channel access manager 935 as described with reference to FIG. 9.

At 1415, the method may include transmitting a sidelink grant indicating that one or more messages are scheduled for transmission via the first sidelink frequency band in a subslot of the first slot. The operations of 1415 may be performed in accordance with examples as disclosed herein. In some examples, aspects of the operations of 1415 may be performed by a transmission manager 940 as described with reference to FIG. 9.

At 1420, the method may include transmitting, in the subslot, the one or more messages via the first sidelink frequency band based on the channel access procedure indicating that the frequency resources are available during the first slot. The operations of 1420 may be performed in accordance with examples as disclosed herein. In some examples, aspects of the operations of 1420 may be performed by a transmission manager 940 as described with reference to FIG. 9.

The following provides an overview of aspects of the present disclosure:
Aspect 1: A method for wireless communications at a first UE, comprising: identifying an automatic gain control parameter that indicates to perform multiple automatic gain control procedures during a slot of a sidelink channel, or the automatic gain control parameter indicates to perform the multiple automatic gain control procedures during the slot based at least in part on an energy detection result for a defined symbol period of the slot, the defined symbol period occurring after a beginning symbol period of the slot; performing, based at least in part on the identifying, a first automatic gain control procedure of the multiple automatic gain control procedures on the beginning symbol period of the slot of to determine a first gain state for receiving a sidelink grant via a sidelink control channel of the slot; receiving, via the sidelink control channel in accordance with the first gain state, the sidelink grant indicating that a sidelink transmission is scheduled for the first UE in a sidelink shared data channel of the slot; and receiving, using the first gain state and a second gain state determined in accordance with the automatic gain control parameter, the sidelink transmission via the sidelink shared data channel of the slot.
Aspect 2: The method of aspect 1, further comprising: performing a first channel estimation procedure for the sidelink shared data channel during a second symbol period of the slot, the first channel estimation procedure using the first gain state; and performing a second channel estimation procedure for the sidelink shared data channel during a third symbol period of the slot, the second channel estimation procedure using the second gain state.
Aspect 3: The method of any of aspects 1 through 2, further comprising: receiving a first demodulation reference signal during a second symbol period of the slot, the second symbol period subsequent to the beginning symbol period of the slot; and receiving a second demodulation reference signal during a third symbol period of the slot, the third symbol period of the slot subsequent to the defined symbol period of the slot.
Aspect 4: The method of any of aspects 1 through 3, wherein the slot comprises a plurality of demodulation reference signal symbol periods and a plurality of automatic gain control symbol periods, each automatic gain control symbol period of the plurality of automatic gain control symbol periods configured based at least in part on a pattern for the plurality of demodulation reference signal symbol periods.
Aspect 5: The method of any of aspects 1 through 4, wherein the slot comprises a first demodulation reference signal symbol period subsequent to a first automatic gain control symbol period and a second demodulation reference signal symbol period subsequent to a second automatic gain control symbol period.
Aspect 6: The method of any of aspects 1 through 5, wherein the slot comprises a same quantity of demodulation reference signal symbol periods and automatic gain control symbol periods.
Aspect 7: The method of any of aspects 1 through 6, further comprising: receiving, from a network entity, control signaling indicating the automatic gain control parameter that indicates to perform a second automatic gain control procedure, wherein the control signaling is based at least in part on whether a quantity of communication links established with the network entity are configured for communications using subslots.
Aspect 8: The method of any of aspects 1 through 7, wherein the control signaling comprises a medium access control control element, radio resource control signaling, or a downlink control information grant, the control signaling received semi-statically.
Aspect 9: The method of any of aspects 1 through 6, further comprising: receiving, from a second UE, control signaling indicating the automatic gain control parameter that indicates to perform a second automatic gain control procedure, wherein the control signaling is based at least in part on the second UE transmitting an automatic gain control signal on the defined symbol period of the slot.
Aspect 10: The method of any of aspects 1 through 6, further comprising: receiving, from a second UE, control signaling indicating the automatic gain control parameter that indicates to perform a second automatic gain control procedure based at least in part on an indication from a network entity to perform the second automatic gain control procedure.
Aspect 11: The method of any of aspects 1 through 6, further comprising: measuring an energy detection result for a third symbol period of the slot, the defined symbol period of the slot subsequent to the third symbol period of the slot; measuring the energy detection result for the defined symbol period of the slot; and comparing the energy detection result for the third symbol period to the energy detection result for the defined symbol period, wherein a second automatic gain control procedure is performed on the defined symbol period of the slot based at least in part on the comparing.
Aspect 12: The method of any of aspects 1 through 6, further comprising: puncturing the defined symbol period based at least in part on a difference between an energy detection result for a third symbol period and the energy detection result for the defined symbol period exceeding a threshold difference.
Aspect 13: The method of any of aspects 1 through 12, wherein the defined symbol period of the slot overlaps with a second beginning symbol period of a subslot of the slot.
Aspect 14: A method for wireless communications, at a first UE, comprising: performing a channel access procedure within frequency resources positioned relative to a first sidelink frequency band to monitor for sidelink control information, a sidelink reference signal, or both, to determine whether full slot transmission by a second UE is scheduled to occur within a first slot, the frequency resources occurring within a threshold frequency offset of the first sidelink frequency band; transmitting a sidelink grant indicating that one or more messages are scheduled for transmission via the first sidelink frequency band in a subslot of the first slot; and transmitting, in the subslot, the one or more messages via the first sidelink frequency band based at least in part on the channel access procedure indicating that the frequency resources are available during the first slot.
Aspect 15: The method of aspect 14, further comprising: receiving control signaling indicating the threshold frequency offset for monitoring for the sidelink control information, the sidelink reference signal, or both, relative to a target sidelink frequency band.
Aspect 16: The method of aspect 15, wherein receiving the control signaling further comprises: receiving the control signaling from the second UE.
Aspect 17: The method of any of aspects 14 through 16, further comprising: performing a second channel access procedure within frequency resources positioned relative to the first sidelink frequency band to monitor for the sidelink control information, the sidelink reference signal, or both; and refraining from transmitting one or more second messages via the first sidelink frequency band based at least in part on the second channel access procedure indicating that the frequency resources are unavailable.
Aspect 18: The method of any of aspects 14 through 17, further comprising: reducing a gain for one or more transmitting components of the first UE based at least in part on a reference signal receive power and a priority for the sidelink control information, the sidelink reference signal, or both.
Aspect 19: The method of any of aspects 14 through 18, wherein the frequency resources are adjacent to the first sidelink frequency band.
Aspect 20: An apparatus for wireless communications at a first UE, comprising one or more processors; one or more memories coupled with the one or more processors; and instructions stored in the one or more memories and executable by the one or more processors to cause the apparatus to perform a method of any of aspects 1 through 13.
Aspect 21: An apparatus for wireless communications at a first UE, comprising at least one means for performing a method of any of aspects 1 through 13.
Aspect 22: A non-transitory computer-readable medium storing code for wireless communications at a first UE, the code comprising instructions executable by one or more processors to perform a method of any of aspects 1 through 13.
Aspect 23: An apparatus for wireless communications, comprising one or more processors; one or more memories coupled with the one or more processors; and instructions stored in the one or more memories and executable by the one or more processors to cause the apparatus to perform a method of any of aspects 14 through 19.
Aspect 24: An apparatus for wireless communications, comprising at least one means for performing a method of any of aspects 14 through 19.
Aspect 25: A non-transitory computer-readable medium storing code for wireless communications, the code comprising instructions executable by one or more processors to perform a method of any of aspects 14 through 19.

It should be noted that the methods described herein describe possible implementations, and that the operations and the steps may be rearranged or otherwise modified and that other implementations are possible. Further, aspects from two or more of the methods may be combined.

Although aspects of an LTE, LTE-A, LTE-A Pro, or NR system may be described for purposes of example, and LTE, LTE-A, LTE-A Pro, or NR terminology may be used in much of the description, the techniques described herein are applicable beyond LTE, LTE-A, LTE-A Pro, or NR networks. For example, the described techniques may be applicable to various other wireless communications systems such as Ultra Mobile Broadband (UMB), Institute of Electrical and Electronics Engineers (IEEE) 802.11 (Wi-Fi), IEEE 802.16 (WiMAX), IEEE 802.20, Flash-OFDM, as well as other systems and radio technologies not explicitly mentioned herein.

Information and signals described herein may be represented using any of a variety of different technologies and techniques. For example, data, instructions, commands, information, signals, bits, symbols, and chips that may be referenced throughout the description may be represented by voltages, currents, electromagnetic waves, magnetic fields or particles, optical fields or particles, or any combination thereof.

The various illustrative blocks and components described in connection with the disclosure herein may be implemented or performed using a general-purpose processor, a DSP, an ASIC, a CPU, an FPGA or other programmable logic device, discrete gate or transistor logic, discrete hardware components, or any combination thereof designed to perform the functions described herein. A general-purpose processor may be a microprocessor but, in the alternative, the processor may be any processor, controller, microcontroller, or state machine. A processor may also be implemented as a combination of computing devices (e.g., a combination of a DSP and a microprocessor, multiple microprocessors, one or more microprocessors in conjunction with a DSP core, or any other such configuration).

The functions described herein may be implemented using hardware, software executed by a processor, firmware, or any combination thereof. If implemented using software executed by a processor, the functions may be stored as or transmitted using one or more instructions or code of a computer-readable medium. Other examples and implementations are within the scope of the disclosure and appended claims. For example, due to the nature of software, functions described herein may be implemented using software executed by a processor, hardware, firmware, hardwiring, or combinations of any of these. Features implementing functions may also be physically located at various positions, including being distributed such that portions of functions are implemented at different physical locations.

Computer-readable media includes both non-transitory computer storage media and communication media including any medium that facilitates transfer of a computer program from one location to another. A non-transitory storage medium may be any available medium that may be accessed by a general-purpose or special-purpose computer. By way of example, and not limitation, non-transitory computer-readable media may include RAM, ROM, electrically erasable programmable ROM (EEPROM), flash memory, compact disk (CD) ROM or other optical disk storage, magnetic disk storage or other magnetic storage devices, or any other non-transitory medium that may be used to carry or store desired program code means in the form of instructions or data structures and that may be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of computer-readable medium. Disk and disc, as used herein, include CD, laser disc, optical disc, digital versatile disc (DVD), floppy disk and Blu-ray disc. Disks may reproduce data magnetically, and discs may reproduce data optically using lasers. Combinations of the above are also included within the scope of computer-readable media.

As used herein, including in the claims, “or” as used in a list of items (e.g., a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an example step that is described as “based on condition A” may be based on both a condition A and a condition B without departing from the scope of the present disclosure. In other words, as used herein, the phrase “based on” shall be construed in the same manner as the phrase “based at least in part on.”

The term “determine” or “determining” encompasses a variety of actions and, therefore, “determining” can include calculating, computing, processing, deriving, investigating, looking up (such as via looking up in a table, a database or another data structure), ascertaining and the like. Also, “determining” can include receiving (e.g., receiving information), accessing (e.g., accessing data stored in memory) and the like. Also, “determining” can include resolving, obtaining, selecting, choosing, establishing, and other such similar actions.

In the appended figures, similar components or features may have the same reference label. Further, various components of the same type may be distinguished by following the reference label by a dash and a second label that distinguishes among the similar components. If just the first reference label is used in the specification, the description is applicable to any one of the similar components having the same first reference label irrespective of the second reference label, or other subsequent reference label.

The description set forth herein, in connection with the appended drawings, describes example configurations and does not represent all the examples that may be implemented or that are within the scope of the claims. The term “example” used herein means “serving as an example, instance, or illustration,” and not “preferred” or “advantageous over other examples.” The detailed description includes specific details for the purpose of providing an understanding of the described techniques. These techniques, however, may be practiced without these specific details. In some instances, known structures and devices are shown in block diagram form in order to avoid obscuring the concepts of the described examples.

The description herein is provided to enable a person having ordinary skill in the art to make or use the disclosure. Various modifications to the disclosure will be apparent to a person having ordinary skill in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

1. An apparatus for wireless communications at a first user equipment (UE), comprising:
one or more processors;
one or more memories coupled with the one or more processors; and instructions stored in the one or more memories and executable by the one or more processors to cause the apparatus to:
identify an automatic gain control parameter that indicates to perform multiple automatic gain control procedures during a slot of a sidelink channel, or the automatic gain control parameter indicates to perform the multiple automatic gain control procedures during the slot based at least in part on an energy detection result for a defined symbol period of the slot, the defined symbol period occurring after a beginning symbol period of the slot;
perform, based at least in part on the identifying, a first automatic gain control procedure of the multiple automatic gain control procedures on the beginning symbol period of the slot to determine a first gain state for receiving a sidelink grant via a sidelink control channel of the slot;
receive, via the sidelink control channel in accordance with the first gain state, the sidelink grant indicating that a sidelink transmission is scheduled for the first UE in a sidelink shared data channel of the slot; and receive, using the first gain state and a second gain state determined in accordance with the automatic gain control parameter, the sidelink transmission via the sidelink shared data channel of the slot.

2. The apparatus of claim 1, wherein the instructions are further executable by the one or more processors to cause the apparatus to:
perform a first channel estimation procedure for the sidelink shared data channel during a second symbol period of the slot, the first channel estimation procedure using the first gain state; and
perform a second channel estimation procedure for the sidelink shared data channel during a third symbol period of the slot, the second channel estimation procedure using the second gain state.

3. The apparatus of claim 1, wherein the instructions are further executable by the one or more processors to cause the apparatus to:
receive a first demodulation reference signal during a second symbol period of the slot, the second symbol period subsequent to the beginning symbol period of the slot; and
receive a second demodulation reference signal during a third symbol period of the slot, the third symbol period of the slot subsequent to the defined symbol period of the slot.

4. The apparatus of claim 1, wherein the slot comprises a plurality of demodulation reference signal symbol periods and a plurality of automatic gain control symbol periods, each automatic gain control symbol period of the plurality of automatic gain control symbol periods configured based at least in part on a pattern for the plurality of demodulation reference signal symbol periods.

5. The apparatus of claim 1, wherein the slot comprises a first demodulation reference signal symbol period subsequent to a first automatic gain control symbol period and a second demodulation reference signal symbol period subsequent to a second automatic gain control symbol period.

6. The apparatus of claim 1, wherein the slot comprises a same quantity of demodulation reference signal symbol periods and automatic gain control symbol periods.

7. The apparatus of claim 1, wherein, to identify the automatic gain control parameter, the instructions are further executable by the one or more processors to cause the apparatus to:
receive, from a network entity, control signaling indicating the automatic gain control parameter that indicates to perform a second automatic gain control procedure, wherein the control signaling is based at least in part on whether a quantity of communication links established with the network entity are configured for communications using subslots.

8. The apparatus of claim 1, wherein the instructions are further executable by the one or more processors to cause the apparatus to:
receive, from a network entity, control signaling, wherein the control signaling comprises a medium access control control element, radio resource control signaling, or a downlink control information grant, the control signaling received semi-statically.

9. The apparatus of claim 1, wherein, to identify the automatic gain control parameter, the instructions are further executable by the one or more processors to cause the apparatus to:
receive, from a second UE, control signaling indicating the automatic gain control parameter that indicates to perform a second automatic gain control procedure, wherein the control signaling is based at least in part on the second UE transmitting an automatic gain control signal on the defined symbol period of the slot.

10. The apparatus of claim 1, wherein, to identify the automatic gain control parameter, the instructions are further executable by the one or more processors to cause the apparatus to:
receive, from a second UE, control signaling indicating the automatic gain control parameter that indicates to perform a second automatic gain control procedure based at least in part on an indication from a network entity to perform the second automatic gain control procedure.

11. The apparatus of claim 1, wherein the instructions are further executable by the one or more processors to cause the apparatus to:
measure an energy detection result for a third symbol period of the slot, the defined symbol period of the slot subsequent to the third symbol period of the slot;
measure the energy detection result for the defined symbol period of the slot; and
compare the energy detection result for the third symbol period to the energy detection result for the defined symbol period, wherein a second automatic gain control procedure is performed on the defined symbol period of the slot based at least in part on the comparing.

12. The apparatus of claim 1, wherein the instructions are further executable by the one or more processors to cause the apparatus to:
puncture the defined symbol period based at least in part on a difference between an energy detection result for a third symbol period and the energy detection result for the defined symbol period exceeding a threshold difference.

13. The apparatus of claim 1, wherein the defined symbol period of the slot overlaps with a second beginning symbol period of a subslot of the slot.

14. An apparatus for wireless communications at a first user equipment (UE), comprising:
one or more processors;
one or more memories coupled with the one or more processors; and instructions stored in the one or more memories and executable by the one or more processors to cause the apparatus to:
perform a channel access procedure within frequency resources positioned relative to a first sidelink frequency band to monitor for sidelink control information, a sidelink reference signal, or both, to determine whether full slot transmission by a second UE is scheduled to occur within a first slot, the frequency resources occurring within a threshold frequency offset of the first sidelink frequency band;
transmit a sidelink grant indicating that one or more messages are scheduled for transmission via the first sidelink frequency band in a subslot of the first slot; and
transmit, in the subslot, the one or more messages via the first sidelink frequency band based at least in part on the channel access procedure indicating that the frequency resources are available during the first slot.

15. The apparatus of claim 14, wherein the instructions are further executable by the one or more processors to cause the apparatus to:
receive control signaling indicating the threshold frequency offset for monitoring for the sidelink control information, the sidelink reference signal, or both, relative to a target sidelink frequency band.

16. The apparatus of claim 15, wherein the instructions to receive the control signaling are further executable by the one or more processors to cause the apparatus to:
receive the control signaling from the second UE.

17. The apparatus of claim 14, wherein the instructions are further executable by the one or more processors to cause the apparatus to:
perform a second channel access procedure within frequency resources positioned relative to the first sidelink frequency band to monitor for the sidelink control information, the sidelink reference signal, or both; and
refrain from transmitting one or more second messages via the first sidelink frequency band based at least in part on the second channel access procedure indicating that the frequency resources are unavailable.

18. The apparatus of claim 14, wherein the instructions are further executable by the one or more processors to cause the apparatus to:
reduce a gain for one or more transmitting components of the first UE based at least in part on a reference signal receive power and a priority for the sidelink control information, the sidelink reference signal, or both.

19. The apparatus of claim 14, wherein the frequency resources are adjacent to the first sidelink frequency band.

20. A method for wireless communications at a first user equipment (UE), comprising:
identifying an automatic gain control parameter that indicates to perform multiple automatic gain control procedures during a slot of a sidelink channel, or the automatic gain control parameter indicates to perform the multiple automatic gain control procedures during the slot based at least in part on an energy detection result for a defined symbol period of the slot, the defined symbol period occurring after a beginning symbol period of the slot;
performing, based at least in part on the identifying, a first automatic gain control procedure of the multiple automatic gain control procedures on the beginning symbol period of the slot to determine a first gain state for receiving a sidelink grant via a sidelink control channel of the slot;
receiving, via the sidelink control channel in accordance with the first gain state, the sidelink grant indicating that a sidelink transmission is scheduled for the first UE in a sidelink shared data channel of the slot; and
receiving, using the first gain state and a second gain state determined in accordance with the automatic gain control parameter, the sidelink transmission via the sidelink shared data channel of the slot.

21-30. (canceled)
